(19) United States
(12) Patent Application Publication
(10) Pub. No.: US 2026/0020326 A1
(43) Pub. Date: Jan. 15, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Shinya SONEDA, Tokyo (JP); Kazuya KONISHI, Tokyo (JP); Wataru HATANO, Fukuoka (JP)

(73) Assignee: Mitsubishi Electric Corporation, Tokyo (JP)

(21) Appl. No.: 19/185,100

(22) Filed: Apr. 21, 2025

(30) Foreign Application Priority Data
Jul. 9, 2024 (JP) 2024-110210

(51) Int. Cl. H10D 84/00; H10D 12/00; H10D 62/10; H10D 64/27; H10D 84/01

(52) U.S. Cl. CPC H10D 84/161; H10D 12/415; H10D 62/107; H10D 64/513; H10D 84/0109; H10D 12/481

(57) ABSTRACT

A semiconductor device includes a plurality of trenches formed on a first main surface of a semiconductor substrate, and insulating films and electrodes formed in the plurality of trenches. The plurality of trenches include a first trench and a second trench deeper than the first trench and wider than the first trench. A bottom layer of a second conductivity type, in contact with a bottom of the second trench and not in contact with the first trench, is disposed under the second trench.

### BACKGROUND

### Technical Field

The present disclosure relates to a semiconductor device and a method of manufacturing a semiconductor device.

### Description of the Background Art

There is known a semiconductor device of a trench gate type having a structure in which a gate electrode is embedded in a trench. For example, Japanese Patent Application Laid-Open No. 2016-225566 below discloses a configuration in which a bottom layer (also referred to as a “BP layer”) that is a p-type semiconductor layer is disposed at a trench bottom of a gate electrode in an IGBT of a trench gate type. The BP layer has an effect of relaxing an electric field at the trench bottom and preventing an avalanche phenomenon of the semiconductor, particularly a transient avalanche phenomenon at the time of interruption after energization called dynamic avalanche.

When a depth (thickness) of the BP layer is increased, the electric field relaxation effect by the BP layer can be enhanced, so that the BP layer is formed to be deep to some extent. However, the BP layer is widened more in the lateral direction when the BP layer is formed deep, and a gap between adjacent trenches is shielded by the BP layer if the BP layer is formed too deep so that the semiconductor device does not operate. Therefore, the depth of the BP layer needs to be designed within a range in which the gap between adjacent trenches is not shielded by the BP layer, and it is sometimes difficult to secure a sufficient depth of the BP layer.

### SUMMARY

An object of the present disclosure is to provide a semiconductor device capable of making a bottom layer deep while preventing the bottom layer from shielding a gap between adjacent trenches.

A semiconductor device according to the present disclosure includes: a semiconductor substrate having a drift layer of a first conductivity type between a first main surface and a second main surface opposite to the first main surface; a plurality of trenches formed on the first main surface of the semiconductor substrate; an insulating film formed on an inner surface of each of the plurality of trenches; and an electrode embedded in each of the plurality of trenches through the insulating film. The plurality of trenches include a first trench and a second trench deeper than the first trench and wider than the first trench. A bottom layer of a second conductivity type, in contact with a bottom of the second trench and not in contact with the first trench, is formed under the second trench.

According to the semiconductor device of the present disclosure, it is possible to make the bottom layer deep while preventing the bottom layer from shielding the gap between adjacent trenches.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a configuration example of a chip of a semiconductor device according to a first preferred embodiment;

FIG. 2 is a plan view illustrating a configuration example of the chip of the semiconductor device according to the first preferred embodiment;

FIG. 3 is a plan view illustrating a configuration example of the chip of the semiconductor device according to the first preferred embodiment;

FIG. 4 is a plan view illustrating an example of a structure of an IGBT region;

FIG. 5 is a cross-sectional view illustrating an example of the structure of the IGBT region;

FIG. 6 is a cross-sectional view illustrating an example of the structure of the IGBT region;

FIG. 7 is a plan view illustrating the structure of the IGBT region of the semiconductor device according to the first preferred embodiment;

FIG. 8 is a cross-sectional view illustrating the structure of the IGBT region of the semiconductor device according to the first preferred embodiment;

FIG. 9 is a cross-sectional view illustrating the structure of the IGBT region of the semiconductor device according to the first preferred embodiment;

FIG. 10 is a plan view illustrating an example of a structure of a diode region;

FIG. 11 is a cross-sectional view illustrating an example of the structure of the diode region;

FIG. 12 is a cross-sectional view illustrating an example of the structure of the diode region;

FIG. 13 is a plan view illustrating the structure of the diode region of the semiconductor device according to the first preferred embodiment;

FIG. 14 is a cross-sectional view illustrating the structure of the diode region of the semiconductor device according to the first preferred embodiment;

FIG. 15 is a cross-sectional view illustrating the structure of the diode region of the semiconductor device according to the first preferred embodiment;

FIG. 16 is a cross-sectional view illustrating an example of a structure of a boundary between the IGBT region and the diode region;

FIG. 17 is a cross-sectional view illustrating an example of a structure of a termination region;

FIG. 18 is a cross-sectional view illustrating an example of the structure of the termination region;

FIG. 19 is a cross-sectional view illustrating an example of the structure of the termination region;

FIG. 20 is a cross-sectional view illustrating an example of the structure of the termination region;

FIG. 21 is a cross-sectional view illustrating the structure of the termination region of the semiconductor device according to the first preferred embodiment;

FIG. 22 is a cross-sectional view illustrating the structure of the termination region of the semiconductor device according to the first preferred embodiment;

FIG. 23 is a view illustrating an example of a method of manufacturing an RC-IGBT;

FIG. 24 is a view illustrating an example of the method of manufacturing an RC-IGBT;

FIG. 25 is a view illustrating an example of the method of manufacturing an RC-IGBT;

FIG. 26 is a view illustrating an example of the method of manufacturing an RC-IGBT;

FIG. 27 is a view illustrating an example of the method of manufacturing an RC-IGBT;

FIG. 28 is a view illustrating an example of the method of manufacturing an RC-IGBT;

FIG. 29 is a view illustrating an example of the method of manufacturing an RC-IGBT;

FIG. 30 is a view illustrating an example of the method of manufacturing an RC-IGBT;

FIG. 31 is a view illustrating an example of the method of manufacturing an RC-IGBT;

FIG. 32 is a view illustrating an example of the method of manufacturing an RC-IGBT;

FIG. 33 is a view illustrating an example of the method of manufacturing an RC-IGBT;

FIG. 34 is a view illustrating an example of the method of manufacturing an RC-IGBT;

FIG. 35 is a view illustrating a method of manufacturing the semiconductor device according to the first preferred embodiment; and

FIG. 36 is a view illustrating the method of manufacturing the semiconductor device according to the first preferred embodiment.

### DESCRIPTION OF THE PREFERRED EMBODIMENTS

In the following description, an n-type and a p-type represent a conductivity type of a semiconductor, and in the present disclosure, a first conductivity type is described as the n-type and a second conductivity type is described as the p-type. However, the first conductivity type may be the p-type and the second conductivity type may be the n-type. In addition, n indicates that impurity concentration is lower than n, and n⁺ indicates that the impurity concentration is higher than n. Similarly, p⁻ indicates that the impurity concentration is lower than p, and p⁺ indicates that the impurity concentration is higher than p.

In addition, a height of the impurity concentration of each region is defined by a peak concentration. That is, the region having a high (or low) impurity concentration means a region having a high (or low) impurity peak concentration.

### First Preferred Embodiment

Hereinafter, a configuration of a semiconductor device according to a first preferred embodiment will be described. As a semiconductor element included in the semiconductor device, a trench gate type semiconductor element, for example, a metal oxide semiconductor field effect transistor (MOSFET), an insulated gate bipolar transistor (IGBT), a reverse conducting IGBT (RC-IGBT), or the like is assumed.

A material of the semiconductor element may be silicon (Si) or a wide band gap semiconductor such as silicon carbide (SiC). The semiconductor device formed using the wide band gap semiconductor is excellent in operation at high voltage, large current, and high temperature as compared with the semiconductor device using silicon. Examples of the wide bandgap semiconductor include gallium nitride (GaN)-based materials and diamond in addition to silicon carbide.

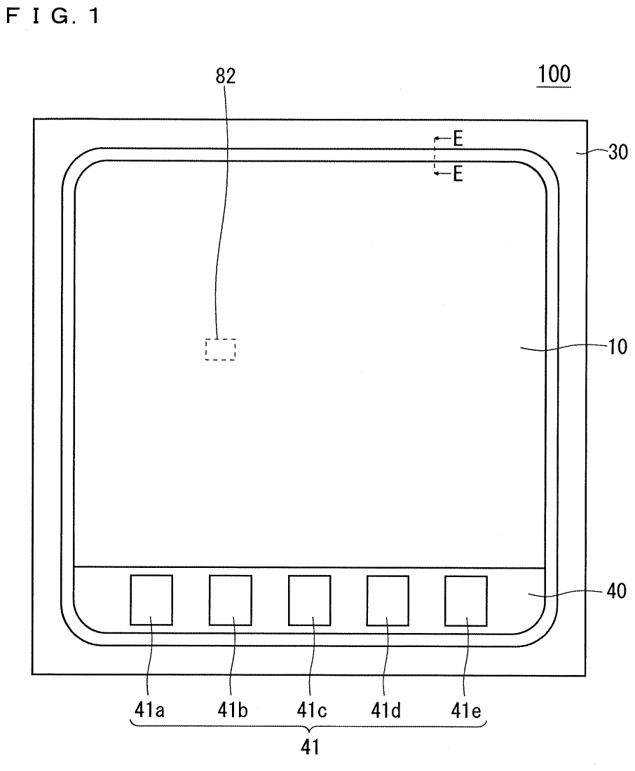

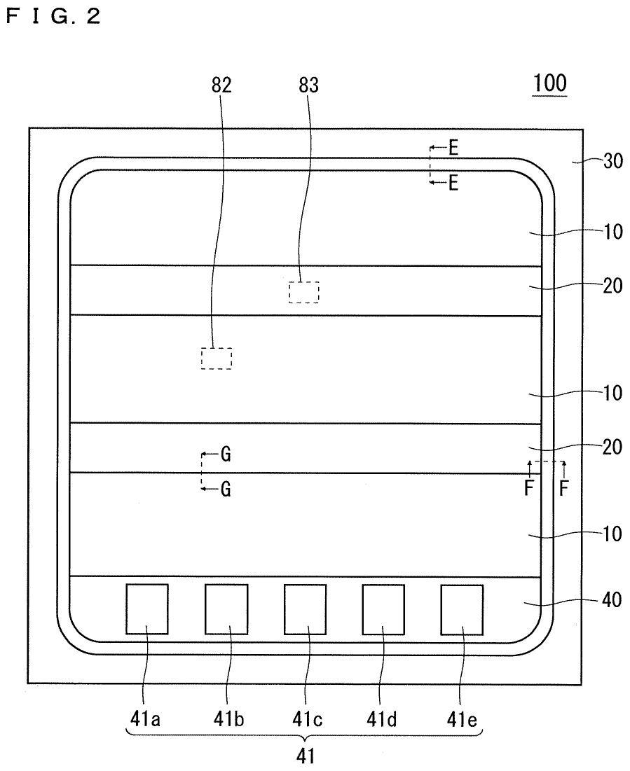

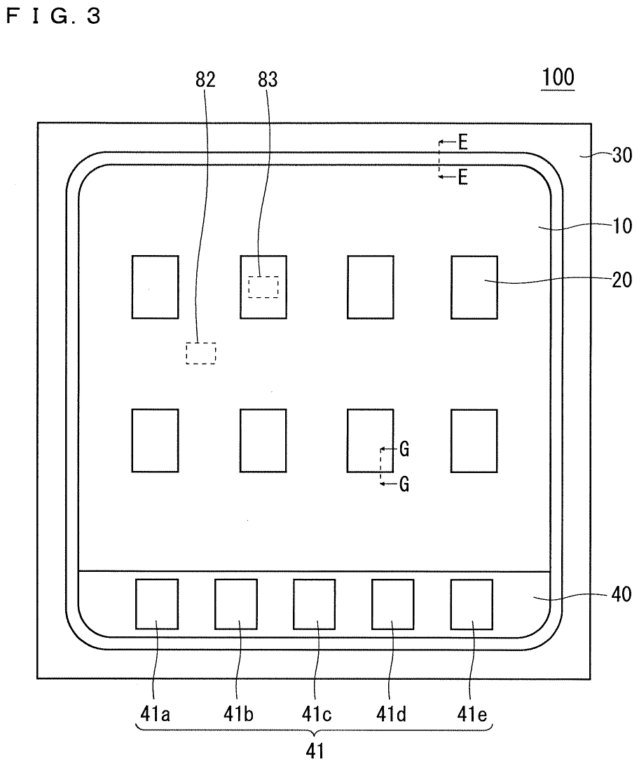

FIGS. 1 to 3 are views illustrating examples of a planar structure of a chip of the semiconductor device according to the first preferred embodiment. FIG. 1 is a plan view illustrating a semiconductor device that is an IGBT. FIG. 2 is a plan view illustrating a semiconductor device that is an RC-IGBT. FIG. 3 is a plan view illustrating a semiconductor device that is an RC-IGBT having another configuration.

An RC-IGBT that is a semiconductor device 100 illustrated in FIG. 2 is provided includes an IGBT region 10 and a diode region 20 provided side by side in a stripe shape, and may also be simply referred to as a “stripe type”. An RC-IGBT that is the semiconductor device 100 illustrated in FIG. 3 includes a plurality of the diode regions 20 provided in the longitudinal direction and the lateral direction, and the IGBT region 10 provided around the diode regions 20, and may also be simply referred to as an “island type”.

### (1) Overall Planar Structure of IGBT

In FIG. 1, the semiconductor device 100 includes the IGBT region 10. A pad region 40 is further provided adjacent to the lower side of the drawing of the IGBT region 10. The pad region 40 is a region where a control pad 41 controlling the semiconductor device 100 is provided. The IGBT region 10 is also referred to as a cell region. A termination region 30 is provided around a combined region of the cell region and the pad region 40 in order to maintain a withstand voltage of the semiconductor device 100. A known withstand voltage holding structure can be appropriately selected and provided in the termination region 30. For example, the withstand voltage holding structure may be configured by providing a field limiting ring (FLR) surrounding a combined region of the cell region and the pad region 40 with a p-type termination well layer of a p-type semiconductor or a variation of lateral doping (VLD) surrounding a combined region of the cell region and the pad region 40 with a p-type termination well layer in which a concentration gradient is provided on a first main surface side that is a front surface side of the semiconductor device 100, and the number of ring-shaped p-type termination well layers used for the FLR and a concentration distribution used for the VLD may be appropriately selected according to the withstand voltage design of the semiconductor device 100. In addition, the p-type termination well layer may be provided over substantially the entire pad region 40, and an IGBT cell may be provided in the pad region 40.

For example, the control pad 41 may be a current sense pad 41a, a Kelvin emitter pad 41b, a gate pad 41c, and temperature sense diode pads 41d, 41e. The current sense pad 41a is the control pad detecting the current flowing through the cell region of the semiconductor device 100, and is the control pad electrically connected to IGBT cells or diode cells in a part of the cell region such that, when the current flows through the cell region of the semiconductor device 100, a several part to a several tens of thousands of part of the current flowing through the entire cell region flows.

The Kelvin emitter pad 41b and the gate pad 41c are control pads to which a gate drive voltage controlling on and off of the semiconductor device 100 is applied. The Kelvin emitter pad 41b is electrically connected to the p-type base layer and an n⁺-type emitter layer of the IGBT cell, and the gate pad 41c is electrically connected to the gate trench electrode of the IGBT cell. The Kelvin emitter pad 41b and the p-type base layer may be electrically connected through a p⁺-type contact layer. The temperature sense diode pads 41d, 41e are control pads electrically connected to an anode and a cathode of a temperature sense diode provided in the semiconductor device 100. The voltage between the anode and the cathode of the temperature sense diode (not illustrated) provided in the cell region is measured to measure temperature at the semiconductor device 100.

### (2) Overall Planar Structure of Stripe-Type RC-IGBT

In FIG. 2, the semiconductor device 100 includes the IGBT region 10 and the diode region 20 in one semiconductor device. The IGBT region 10 and the diode region 20 extend from one end side to the other end side of the semiconductor device 100, and are alternately provided in the stripe shape in a direction orthogonal to an extending direction of the IGBT region 10 and the diode region 20. In FIG. 2, three IGBT regions 10 and two diode regions 20 are illustrated, and all the diode regions 20 are sandwiched between the IGBT regions 10. However, the number of the IGBT regions 10 and the number of the diode regions 20 are not limited thereto, and the number of the IGBT regions 10 may be equal to and greater than three and equal to or smaller than three, and the number of the diode regions 20 may be equal to or greater than two and equal to or smaller than two. In addition, locations of the IGBT region 10 and the diode region 20 in FIG. 2 may be interchanged, or all the IGBT regions 10 may be sandwiched between the diode regions 20. In addition, the IGBT region 10 and the diode region 20 may be provided adjacent to each other one by one.

As illustrated in FIG. 2, the pad region 40 is provided adjacent to the lower side of the drawing of the IGBT region 10. The pad region 40 is a region where a control pad 41 controlling the semiconductor device 100 is provided. The IGBT region 10 and the diode region 20 are also collectively referred to as a cell region. A termination region 30 is provided around a combined region of the cell region and the pad region 40 in order to maintain a withstand voltage of the semiconductor device 100. A known withstand voltage holding structure can be appropriately selected and provided in the termination region 30.

For example, the withstand voltage holding structure may be configured by providing a field limiting ring (FLR) surrounding a combined region of the cell region and the pad region 40 with a p-type termination well layer of a p-type semiconductor or a variation of lateral doping (VLD) surrounding a combined region of the cell region and the pad region 40 with a p-type termination well layer in which a concentration gradient is provided on a first main surface side that is a front surface side of the semiconductor device 100, and the number of ring-shaped p-type termination well layers used for the FLR and a concentration distribution used for the VLD may be appropriately selected according to the withstand voltage design of the semiconductor device 100. In addition, the p-type termination well layer may be provided over substantially the entire pad region 40, and an IGBT cell and a diode cell may be provided in the pad region 40.

For example, the control pad 41 may be the current sense pad 41a, the Kelvin emitter pad 41b, the gate pad 41c, and the temperature sense diode pads 41d, 41e. The current sense pad 41a is the control pad detecting the current flowing through the cell region of the semiconductor device 100, and is the control pad electrically connected to IGBT cells or diode cells in a part of the cell region such that, when the current flows through the cell region of the semiconductor device 100, a several part to a several tens of thousands of part of the current flowing through the entire cell region flows.

The Kelvin emitter pad 41b and the gate pad 41c are control pads to which a gate drive voltage controlling on and off of the semiconductor device 100 is applied. The Kelvin emitter pad 41b is electrically connected to the p-type base layer and an n⁺-type emitter layer of the IGBT cell, and the gate pad 41c is electrically connected to the gate trench electrode of the IGBT cell. The Kelvin emitter pad 41b and the p-type base layer may be electrically connected through a p⁺-type contact layer. The temperature sense diode pads 41d, 41e are control pads electrically connected to an anode and a cathode of a temperature sense diode provided in the semiconductor device 100. The voltage between the anode and the cathode of the temperature sense diode (not illustrated) provided in the cell region is measured to measure temperature at the semiconductor device 100.

### (3) Overall Planar Structure of Island Type

In FIG. 3, the semiconductor device 100 includes the IGBT region 10 and the diode region 20 in one semiconductor device. A plurality of diode regions 20 are arranged side by side in the longitudinal direction and the lateral direction in the semiconductor device, and the diode region 20 is surrounded by the IGBT region 10. That is, the plurality of diode regions 20 are provided in the island shape in the IGBT region 10. In FIG. 3, the diode regions 20 are provided in a matrix of four columns in a horizontal direction on the drawing and two rows in an upper limit direction on the drawing. However, the number and disposition of the diode regions 20 are not limited thereto, and one or a plurality of diode regions 20 may be provided in the IGBT region 10 in an interspersed manner, and each of the diode regions 20 may be surrounded by the IGBT region 10.

As illustrated in FIG. 3, the pad region 40 is provided adjacent to the lower side of the drawing of the IGBT region 10. The pad region 40 is a region where a control pad 41 controlling the semiconductor device 100 is provided. The IGBT region 10 and the diode region 20 are also collectively referred to as a cell region. A termination region 30 is provided around a combined region of the cell region and the pad region 40 in order to maintain a withstand voltage of the semiconductor device 100. A known withstand voltage holding structure can be appropriately selected and provided in the termination region 30. For example, the withstand voltage holding structure may be configured by providing a field limiting ring (FLR) surrounding a combined region of the cell region and the pad region 40 with a p-type termination well layer of a p-type semiconductor or a variation of lateral doping (VLD) surrounding a combined region of the cell region and the pad region 40 with a p-type termination well layer in which a concentration gradient is provided on a first main surface side that is a front surface side of the semiconductor device 100, and the number of ring-shaped p-type termination well layers used for the FLR and a concentration distribution used for the VLD may be appropriately selected according to the withstand voltage design of the semiconductor device 100. In addition, the p-type termination well layer may be provided over substantially the entire pad region 40, and an IGBT cell and a diode cell may be provided in the pad region 40.

For example, the control pad 41 may be the current sense pad 41a, the Kelvin emitter pad 41b, the gate pad 41c, and the temperature sense diode pads 41d, 41e. The current sense pad 41a is the control pad detecting the current flowing through the cell region of the semiconductor device 100, and is the control pad electrically connected to IGBT cells or diode cells in a part of the cell region such that, when the current flows through the cell region of the semiconductor device 100, a several part to a several tens of thousands of part of the current flowing through the entire cell region flows.

The Kelvin emitter pad 41b and the gate pad 41c are control pads to which a gate drive voltage controlling on and off of the semiconductor device 100 is applied. The Kelvin emitter pad 41b is electrically connected to the p-type base layer and an n⁺-type emitter layer of the IGBT cell, and the gate pad 41c is electrically connected to the gate trench electrode of the IGBT cell. The Kelvin emitter pad 41b and the p-type base layer may be electrically connected through a p⁺-type contact layer. The temperature sense diode pads 41d, 41e are control pads electrically connected to an anode and a cathode of a temperature sense diode provided in the semiconductor device 100. The voltage between the anode and the cathode of the temperature sense diode (not illustrated) provided in the cell region is measured to measure temperature at the semiconductor device 100.

### (4) Example of Structure of IGBT Region 10

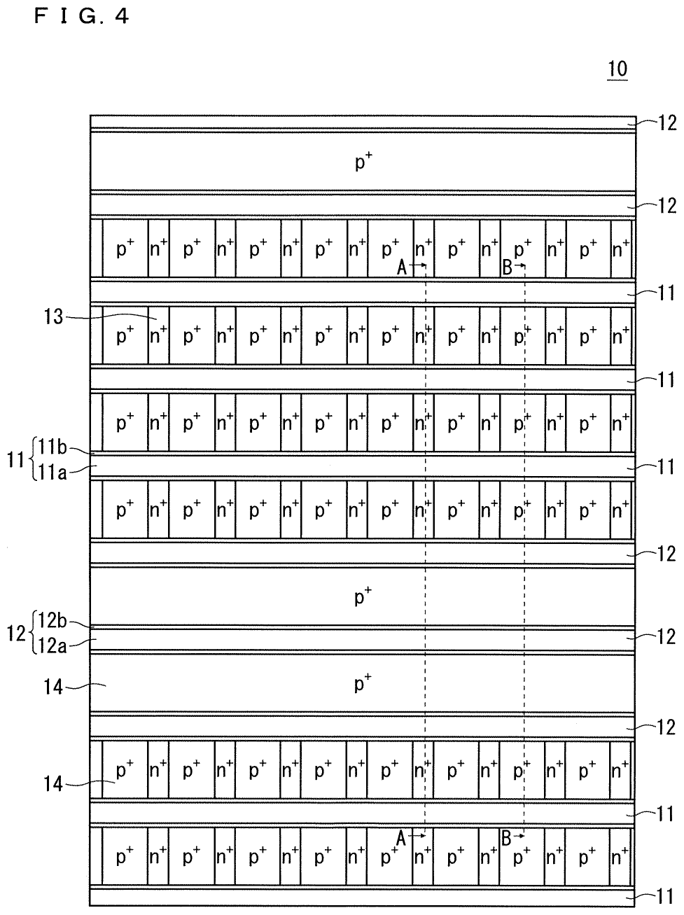

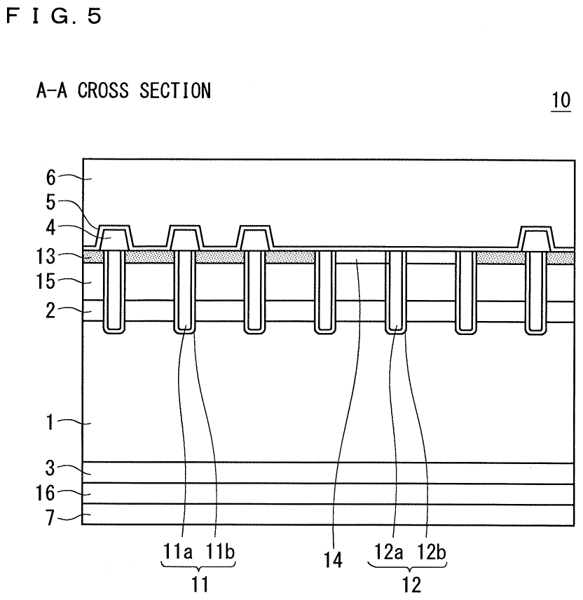

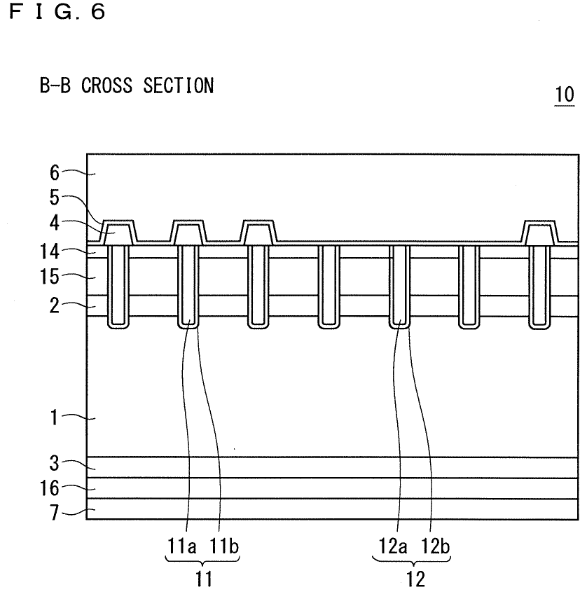

FIG. 4 is a partially enlarged plan view illustrating a configuration of an IGBT region of a semiconductor device that is an RC-IGBT. FIGS. 5 and 6 are cross-sectional views each illustrating a configuration of the IGBT region of the semiconductor device that is the RC-IGBT. FIG. 4 is an enlarged view illustrating a region surrounded by a broken line 82 in the semiconductor device 100 illustrated in FIG. 2 or the semiconductor device 100 illustrated in FIG. 3. FIG. 5 is a cross-sectional view taken along a broken line A-A of the semiconductor device 100 illustrated in FIG. 4, and FIG. 6 is a cross-sectional view taken along a broken line B-B of the semiconductor device 100 illustrated in FIG. 4.

As illustrated in FIG. 4, in the IGBT region 10, an active trench gate 11 and a dummy trench gate 12 are provided in a stripe shape. In the stripe-type RC-IGBT, the active trench gate 11 and the dummy trench gate 12 extend in a longitudinal direction of the IGBT region 10, and the longitudinal direction of the IGBT region 10 is a longitudinal direction of the active trench gate 11 and the dummy trench gate 12. On the other hand, in the island-type RC-IGBT, there is no particular distinction between the longitudinal direction and a lateral direction in the IGBT region 10, but the lateral direction on the drawing may be the longitudinal direction of the active trench gate 11 and the dummy trench gate 12, and a vertical direction on the drawing may be the longitudinal direction of the active trench gate 11 and the dummy trench gate 12.

The active trench gate 11 is configured such that a gate trench electrode 11a is provided in a trench formed in the semiconductor substrate through a gate trench insulating film 11b. The dummy trench gate 12 is configured such that a dummy trench electrode 12a is provided in the trench formed in the semiconductor substrate through a dummy trench insulating film 12b. The gate trench electrode 11a of the active trench gate 11 is electrically connected to the gate pad 41c. The dummy trench electrode 12a of the dummy trench gate 12 is electrically connected to an emitter electrode provided on a first main surface of the semiconductor device 100.

An n⁺-type emitter layer 13 is provided on both sides in a width direction of the active trench gate 11 so as to be in contact with the gate trench insulating film 11b. The n⁺-type emitter layer 13 is a semiconductor layer containing, for example, arsenic or phosphorus as an n-type impurity, and the concentration of the n-type impurity is 1.0E+17/cm³ to 1.0E+20/cm³. The n⁺-type emitter layer 13 and a p⁺-type contact layer 14 are alternately provided along the extending direction of the active trench gate 11. The p⁺-type contact layer 14 is also provided between two adjacent dummy trench gates 12. The p⁺-type contact layer 14 is a semiconductor layer containing, for example, boron or aluminum as a p-type impurity, and the concentration of the p-type impurity is 1.0E+15/cm³ to 1.0E+20/cm³.

As illustrated in FIG. 4, in the IGBT region 10 of the semiconductor device 100, three dummy trench gates 12 are arranged next to three active trench gates 11, and three active trench gates 11 are arranged next to three dummy trench gates 12. The IGBT region 10 has a configuration in which a set of active trench gates 11 and a set of dummy trench gates 12 are alternately arranged as described above. In FIG. 4, the number of the active trench gates 11 included in one set of active trench gates 11 is three, but may be equal to or greater than one. In addition, the number of dummy trench gates 12 included in one set of one dummy trench gate 12 may be equal to or greater than one, and the number of dummy trench gates 12 may be zero. That is, all the trenches provided in the IGBT region 10 may be used as the active trench gate 11.

FIG. 5 is the cross-sectional view of the semiconductor device 100 taken along the broken line A-A of FIG. 4, and is a cross-sectional view of the IGBT region 10. The semiconductor device 100 includes an n⁻-type drift layer 1 made of a semiconductor substrate. The n⁻-type drift layer 1 is a semiconductor layer containing, for example, arsenic or phosphorus as the n-type impurity, and the concentration of the n-type impurity is 1.0E+12/cm³ to 1.0E+15/cm³. In FIG. 5, the semiconductor substrate is in a range from the n⁺-type emitter layer 13 and the p⁺-type contact layer 14 to a p-type collector layer 16. In FIG. 5, upper ends of the n⁺-type emitter layer 13 and the p⁺-type contact layer 14 on the drawing are referred to as a first main surface of the semiconductor substrate, and a lower end of the p-type collector layer 16 on the drawing is referred to as a second main surface of the semiconductor substrate. The first main surface of the semiconductor substrate is a main surface on a front surface side of the semiconductor device 100, and the second main surface of the semiconductor substrate is a main surface on a back surface side of the semiconductor device 100. The semiconductor device 100 includes the n⁻-type drift layer 1 between the first main surface and the second main surface opposite to the first main surface in the IGBT region 10 that is the cell region.

As illustrated in FIG. 5, in the IGBT region 10, an n-type carrier stored layer 2 having a higher n-type impurity concentration than the n⁻-type drift layer 1 is provided on the first main surface side of the n⁻-type drift layer 1. The n-type carrier stored layer 2 is a semiconductor layer containing, for example, arsenic or phosphorus as the n-type impurity, and the concentration of the n-type impurity is 1.0E+13/cm³ to 1.0E+17/cm³. Note that the semiconductor device 100 may have a configuration in which the n-type carrier stored layer 2 is not provided and the n-type drift layer 1 is also provided in a region of the n-type carrier stored layer 2 illustrated in FIG. 5. The provision of the n-type carrier stored layer 2 can reduce an energization loss when the current flows in the IGBT region 10. The n-type carrier stored layer 2 and the n⁻-type drift layer 1 may be collectively referred to as a drift layer.

The n-type carrier stored layer 2 is formed by ion-implanting the n-type impurity into the semiconductor substrate configuring the n⁻-type drift layer 1 and then diffusing the n-type impurity implanted by annealing into the semiconductor substrate that is the n⁻-type drift layer 1.

A p-type base layer 15 is provided on the first main surface side of the n-type carrier stored layer 2. The p-type base layer 15 is a semiconductor layer containing, for example, boron or aluminum as the p-type impurity, and the concentration of the p-type impurity is 1.0E+12/cm³ to 1.0E+19/cm³. The p-type base layer 15 is in contact with the gate trench insulating film 11b of the active trench gate 11. On the first main surface side of the p-type base layer 15, the n⁺-type emitter layer 13 is provided in contact with the gate trench insulating film 11b of the active trench gate 11, and the p⁺-type contact layer 14 is provided in the remaining region. The n⁺-type emitter layer 13 and the p⁺-type contact layer 14 configure the first main surface of the semiconductor substrate. The p⁺-type contact layer 14 is a region having a higher p-type impurity concentration than the p-type base layer 15, and when the p⁺-type contact layer 14 and the p-type base layer 15 are required to be distinguished from each other, they may be referred to individually, and the p⁺-type contact layer 14 and the p-type base layer 15 may be collectively referred to as a p-type base layer.

In the semiconductor device 100, an n-type buffer layer 3 having a higher n-type impurity concentration than the n⁻-type drift layer 1 is provided on the second main surface side of the n⁻-type drift layer 1. The n-type buffer layer 3 is provided to prevent punch-through of a depletion layer extending from the p-type base layer 15 to the second main surface side when the semiconductor device 100 is in an off-state. The n-type buffer layer 3 may be formed by, for example, implanting the phosphorus (P) or proton (H⁺), or implanting both the phosphorus (P) and the proton (H⁺). The concentration of the n-type impurity in the n-type buffer layer 3 is 1.0E+12/cm³ to 1.0E+18/cm³.

Note that the semiconductor device 100 may have a configuration in which the n-type buffer layer 3 is not provided and the n-type drift layer 1 is provided also in a region of the n-type buffer layer 3 illustrated in FIG. 5. The n-type buffer layer 3 and the n⁻-type drift layer 1 may be collectively referred to as a drift layer.

In the semiconductor device 100, the p-type collector layer 16 is provided on the second main surface side of the n-type buffer layer 3. That is, the p-type collector layer 16 is provided between the n⁻-type drift layer 1 and the second main surface. The p-type collector layer 16 is a semiconductor layer containing, for example, boron or aluminum as the p-type impurity, and the concentration of the p-type impurity is 1.0E+16/cm³ to 1.0E+20/cm³. The p-type collector layer 16 configures the second main surface of the semiconductor substrate. The p-type collector layer 16 is provided not only in the IGBT region 10 but also in the termination region 30, and a portion of the p-type collector layer 16 provided in the termination region 30 configures a p-type termination collector layer 16a. In addition, the p-type collector layer 16 may be provided so as to partially protrude from the IGBT region 10 to the diode region 20.

As illustrated in FIG. 5, trenches each penetrating the p-type base layer 15 from the first main surface of the semiconductor substrate and reaching the n⁻-type drift layer 1 are formed in the semiconductor device 100. The gate trench electrode 11a is provided in the trench through the gate trench insulating film 11b to configure the active trench gate 11. The gate trench electrode 11a is opposite to the n⁻-type drift layer 1 through the gate trench insulating film 11b. The dummy trench electrode 12a is provided in the trench through the dummy trench insulating film 12b to configure the dummy trench gate 12. The dummy trench electrode 12a is opposite to the n-type drift layer 1 through the dummy trench insulating film 12b. The gate trench insulating film 11b of the active trench gate 11 is in contact with the p-type base layer 15 and the n⁺-type emitter layer 13. When the gate drive voltage is applied to the gate trench electrode 11a, a channel is formed in the p-type base layer 15 that is in contact with the gate trench insulating film 11b of the active trench gate 11.

As illustrated in FIG. 5, an interlayer insulating film 4 is provided on the gate trench electrode 11a of the active trench gate 11. A barrier metal 5 is formed on the region of the first main surface of the semiconductor substrate where the interlayer insulating film 4 is not provided and on the interlayer insulating film 4. For example, the barrier metal 5 may be a conductor containing titanium (Ti), and may be titanium nitride or TiSi obtained by alloying titanium and silicon (Si). As illustrated in FIG. 5, the barrier metal 5 is in ohmic contact with the n⁺-type emitter layer 13, the p⁺-type contact layer 14, and the dummy trench electrode 12a, and is electrically connected to the n⁺-type emitter layer 13, the p⁺-type contact layer 14, and the dummy trench electrode 12a. An emitter electrode 6 is provided on the barrier metal 5. For example, the emitter electrode 6 may be formed of an aluminum alloy such as an aluminum silicon alloy (Al—Si-based alloy), or may be an electrode including a plurality of layers of metal films in which a plating film is formed on an electrode formed of an aluminum alloy by electroless plating or electrolytic plating. For example, the plating film formed by the electroless plating or the electrolytic plating may be a nickel (Ni) plating film. In addition, in the case of a fine region between adjacent interlayer insulating films 4 or the like and a region where favorable embedding cannot be obtained in the emitter electrode 6, tungsten having better embeddability than the emitter electrode 6 may be disposed in the fine region, and the emitter electrode 6 may be provided on the tungsten. The emitter electrode 6 may be provided on the n⁺-type emitter layer 13, the p⁺-type contact layer 14, and the dummy trench electrode 12a without providing the barrier metal 5. Alternatively, the barrier metal 5 may be provided only on the n-type semiconductor layer such as the n⁺-type emitter layer 13. The barrier metal 5 and the emitter electrode 6 may be collectively referred to as an emitter electrode. Although FIG. 5 illustrates a view in which the interlayer insulating film 4 is not provided on the dummy trench electrode 12a of the dummy trench gate 12, the interlayer insulating film 4 may be formed on the dummy trench electrode 12a of the dummy trench gate 12. When the interlayer insulating film 4 is formed on the dummy trench electrode 12a of the dummy trench gate 12, the emitter electrode 6 and the dummy trench electrode 12a may be electrically connected in another section.

A collector electrode 7 is provided on the second main surface side of the p-type collector layer 16. Similarly to the emitter electrode 6, the collector electrode 7 may be made of an aluminum alloy or an aluminum alloy and a plating film. The collector electrode 7 may have a configuration different from that of the emitter electrode 6. The collector electrode 7 is in ohmic contact with the p-type collector layer 16 and is electrically connected to the p-type collector layer 16.

FIG. 6 is a cross-sectional view of the semiconductor device 100 taken along the broken line B-B of FIG. 4, and is a cross-sectional view of the IGBT region 10. A difference from the cross-sectional view taken along the broken line A-A illustrated in FIG. 5 is that the n⁺-type emitter layer 13 provided on the first main surface side of the semiconductor substrate in contact with the active trench gate 11 is not seen in the cross-sectional view taken along the broken line B-B in FIG. 6. That is, as illustrated in FIG. 4, the n⁺-type emitter layer 13 is selectively provided on the first main surface side of a p-type base layer. The p-type base layer referred to herein is a p-type base layer in which the p-type base layer 15 and the p⁺-type contact layer 14 are collectively referred to.

### (5) Structure of IGBT Region 10 According to Present Preferred Embodiment

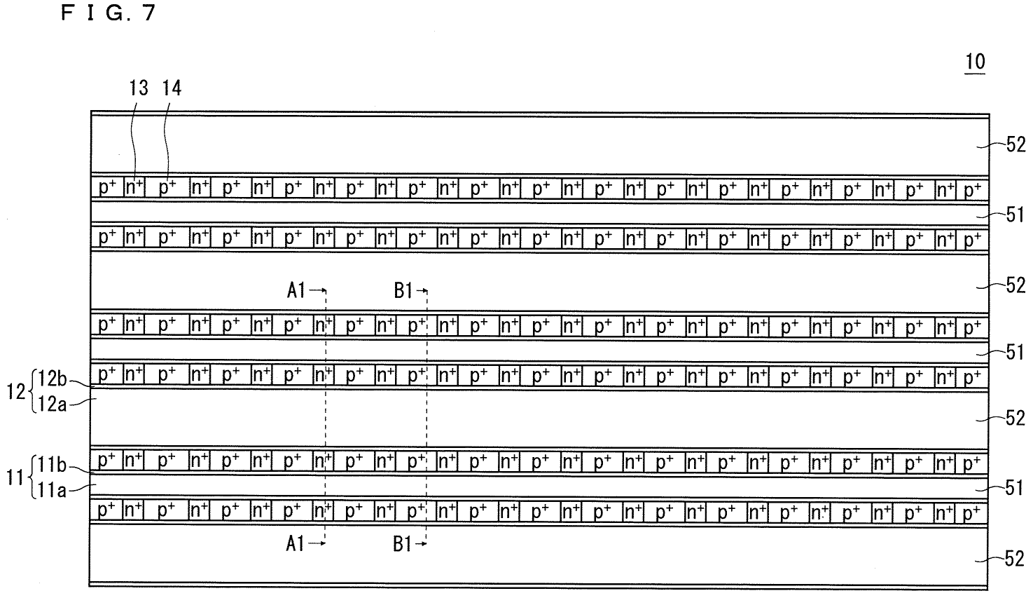

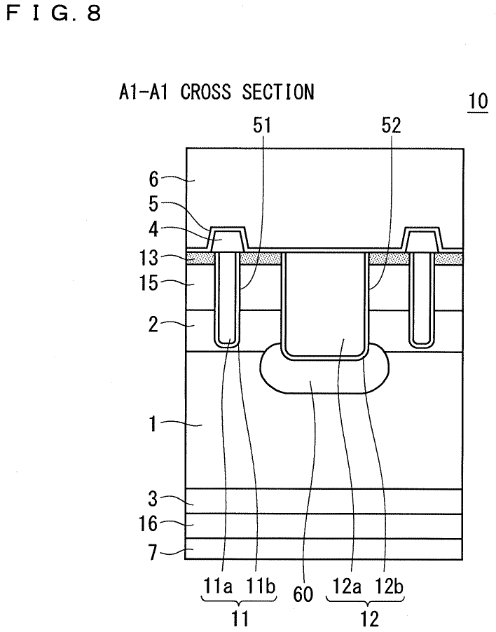

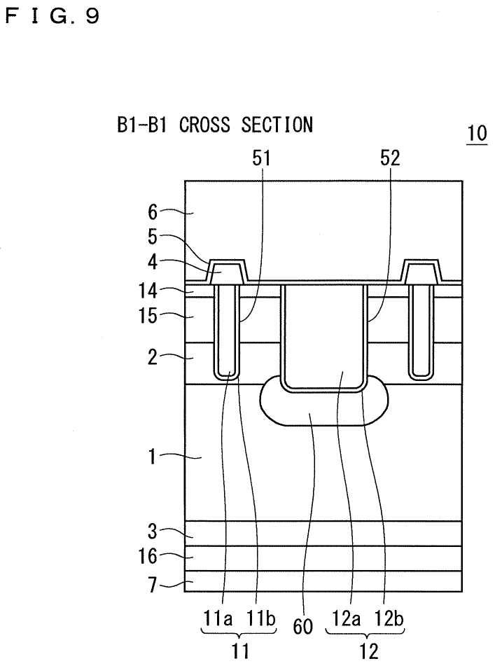

FIGS. 7 to 9 are views each illustrating a structure of the IGBT region 10 of the semiconductor device 100 according to the first preferred embodiment. FIG. 7 is an enlarged plan view of a part of the IGBT region 10. FIGS. 8 and 9 are cross-sectional views each illustrating a configuration of an IGBT disposed in the IGBT region 10. FIG. 7 is an enlarged view illustrating a region surrounded by the broken line 82 in the semiconductor device 100 illustrated in FIG. 1, 2, or 3. FIG. 8 is a cross-sectional view taken along a broken line A1-A1 illustrated in FIG. 7, and FIG. 9 is a cross-sectional view taken along a broken line B1-B1 illustrated in FIG. 7.

As illustrated in FIGS. 7 to 9, first trenches 51 and second trenches 52 having different widths are disposed in the IGBT region 10 of the semiconductor device 100 according to the first preferred embodiment. The width of the second trenches 52 is wider than the width of the first trenches 51. The active trench gate 11 including the gate trench electrode 11a and the gate trench insulating film 11b is formed in each of the first trenches 51, and the dummy trench gate 12 including the dummy trench electrode 12a and the dummy trench insulating film 12b is formed in each of the second trenches 52 (as can be seen from FIGS. 8 and 9, the dummy trench electrode 12a in each of the second trenches 52 is connected to the emitter electrode 6 through the barrier metal 5 and does not function as a gate electrode of the IGBT). Although the entire upper surface of the dummy trench electrode 12a is connected to the emitter electrode 6 through the barrier metal 5 in FIGS. 8 and 9, the upper surface of the dummy trench electrode 12a may be partially covered with the interlayer insulating film 4.

Here, a direction from the first main surface (surface on the upper side of the drawing in FIGS. 8 and 9) of the semiconductor substrate toward the second main surface (surface on the lower side of the drawing in FIGS. 8 and 9), that is, a depth direction from the first main surface of the semiconductor substrate is defined as a “first direction”. In addition, a direction perpendicular to the first direction and perpendicular to a longitudinal direction of the first trench 51 and the second trench 52, that is, a width direction of the first trench 51 and the second trench 52 is defined as a “second direction”. That is, the first direction is a downward direction on the drawing in FIGS. 8 and 9, and the second direction is a lateral direction on the drawing in FIGS. 8 and 9.

As illustrated in FIGS. 8 and 9, a depth of the second trench 52 is deeper than a depth of the first trench 51 in the first direction, and the width of the second trench 52 is wider than the width of the first trench 51 in the second direction. In addition, a p-type bottom layer 60 is formed at a bottom of the second trench 52 so as to be in contact with the second trench 52. The p-type bottom layer 60 is not formed at a bottom of the first trench 51. In addition, the p-type bottom layer 60 at the bottom of the second trench 52 is formed so as not to be in contact with the first trench 51.

Since the second trenches 52 are deeper than the first trenches 51, a distance between the bottoms of the second trenches 52 in which the p-type bottom layers 60 are provided becomes long, so that the adjacent p-type bottom layers 60 are prevented from being connected, and the p-type bottom layers 60 are prevented from shielding a gap between trenches. Therefore, the p-type bottom layers 60 can be formed deeper. In addition, since the widths of the second trenches 52 are wide, regions occupied by the p-type bottom layers 60 can be increased, and an electric field relaxation effect by the p-type bottom layers 60 can be enhanced.

In the present preferred embodiment, the n-type carrier stored layer 2 is disposed between the p-type base layer 15 and the p-type bottom layer 60, and the p-type bottom layer 60 is in contact with the n-type carrier stored layer 2. With this disposition, the p-type bottom layer 60 is further prevented from being diffused in the lateral direction, and an effect of preventing the p-type bottom layer 60 from shielding the gap between trenches is improved.

In addition, a bottom of the n-type carrier stored layer 2 is made deeper than the bottom of the first trench 51. With this configuration, the diffusion of the p-type bottom layer 60 in the lateral direction is further prevented. However, an electric field generated in the n-type carrier stored layer 2 increases if the bottom of the n-type carrier stored layer 2 becomes deeper than a bottom of the p-type bottom layer 60, and thus the bottom of the n-type carrier stored layer 2 is preferably shallower than the bottom of the p-type bottom layer 60.

Here, the example in which the active trench gate 11 is formed in the first trench 51 and the dummy trench gate 12 is formed in the second trench 52 has been described, but conversely, the dummy trench gate 12 may be formed in the first trench 51, and the dummy trench gate 12 may be formed in the second trench 52.

Although the first trenches 51 and the second trenches 52 are alternately arranged one by one in FIG. 7, the IGBT region 10 may have a region in which the plurality of first trenches 51 are continuously disposed side by side and a region in which the plurality of second trenches 52 are continuously disposed side by side. That is, it is not necessary that all the first trenches 51 are adjacent to the second trenches 52, and it is sufficient that at least some of the first trenches 51 are adjacent to the second trenches 52. Similarly, it is not necessary that all the second trenches 52 are adjacent to the first trenches 51, and it is sufficient that at least some of the second trenches 52 are adjacent to the first trenches 51. In a case where the dummy trench gates 12 are formed in the second trenches 52, respectively, the p-type bottom layers 60 at the bottoms of the adjacent second trenches 52 may be connected to each other in a region where the second trenches 52 are continuously disposed side by side.

### (6) Example of Structure of Diode Region 20

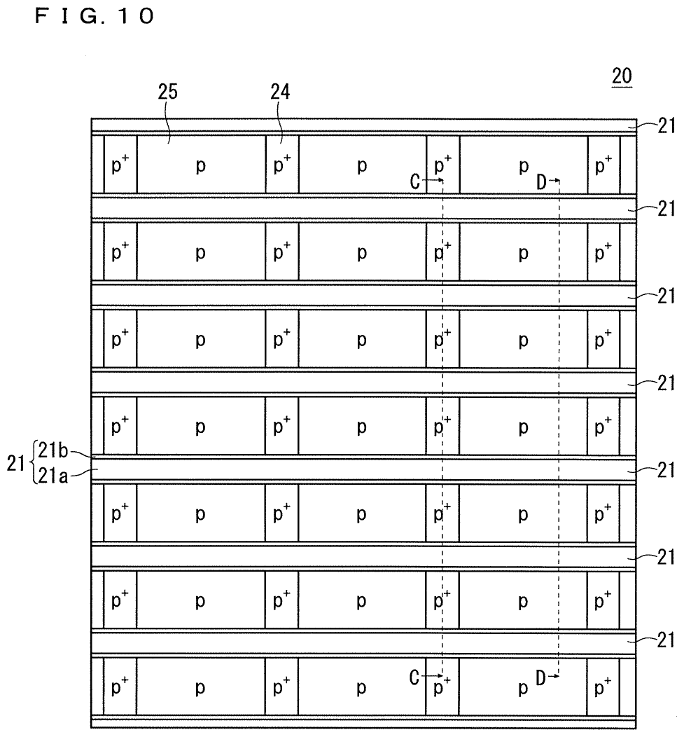

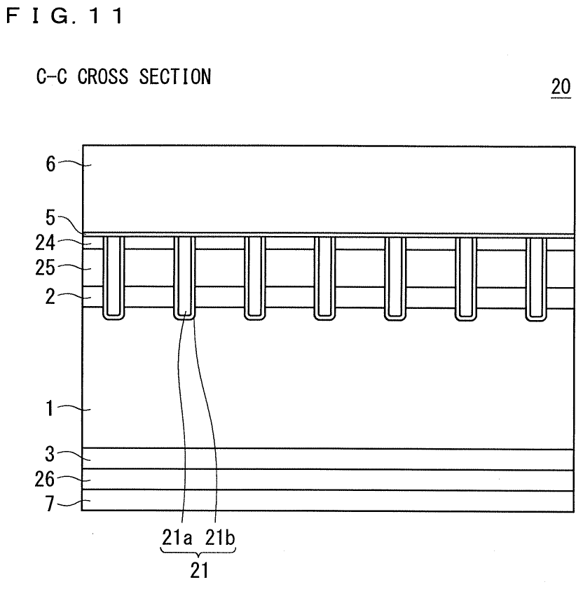

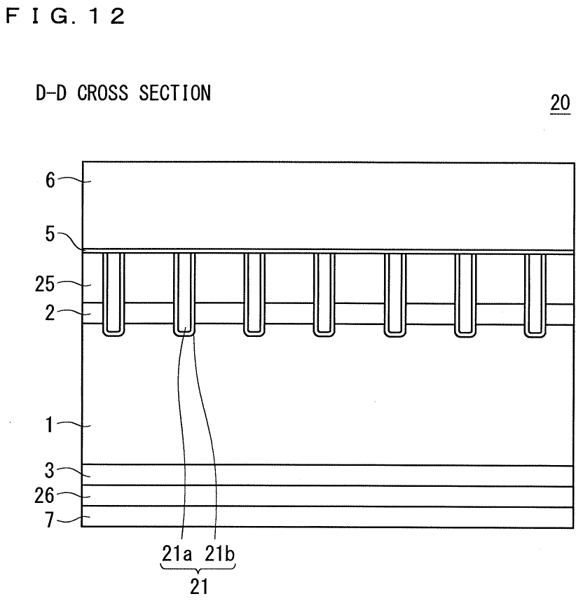

FIG. 10 is a partially enlarged plan view illustrating a configuration of a diode region of a semiconductor device that is an RC-IGBT. FIGS. 11 and 12 are cross-sectional views each illustrating the configuration of the diode region of the semiconductor device that is the RC-IGBT. FIG. 10 is an enlarged view illustrating a region surrounded by a broken line 83 in the semiconductor device 100 illustrated in FIG. 2. FIG. 11 is a cross-sectional view taken along a broken line C-C of the semiconductor device 100 illustrated in FIG. 10. FIG. 12 is a cross-sectional view taken along a broken line D-D of the semiconductor device 100 illustrated in FIG. 10.

A diode trench gate 21 extends along the first main surface of the semiconductor device 100 from one end side of the diode region 20, which is the cell region, toward the opposite end side. The diode trench gate 21 is configured by providing a diode trench electrode 21a in the trench formed in the semiconductor substrate of the diode region 20 through a diode trench insulating film 21b. The diode trench electrode 21a is opposite to the n⁻-type drift layer 1 through the diode trench insulating film 21b. A p⁺-type contact layer 24 and a p-type anode layer 25 are provided between the two adjacent diode trench gates 21. The p⁺-type contact layer 24 is a semiconductor layer containing, for example, boron or aluminum as a p-type impurity, and the concentration of the p-type impurity is 1.0E+15/cm³ to 1.0E+20/cm³. The p-type anode layer 25 is a semiconductor layer containing, for example, boron or aluminum as the p-type impurity, and the concentration of the p-type impurity is 1.0E+12/cm³ to 1.0E+19/cm³. The p⁺-type contact layer 24 and the p-type anode layer 25 are alternately provided in the longitudinal direction of the diode trench gate 21.

FIG. 11 is the cross-sectional view of the semiconductor device 100 taken along the broken line C-C of FIG. 10, and is a cross-sectional view of the diode region 20. The semiconductor device 100 also includes the n⁻-type drift layer 1 including a semiconductor substrate in the diode region 20 as in the IGBT region 10. The n⁻-type drift layer 1 of the diode region 20 and the n⁻-type drift layer 1 of the IGBT region 10 are continuously and integrally formed, and are formed of the same semiconductor substrate. In FIG. 11, the semiconductor substrate ranges from the p⁺-type contact layer 24 to an n⁺-type cathode layer 26. In FIG. 11, an upper end of the p⁺-type contact layer 24 on the drawing is referred to as a first main surface of the semiconductor substrate, and a lower end of the n⁺-type cathode layer 26 on the drawing is referred to as a second main surface of the semiconductor substrate. The first main surface of the diode region 20 and the first main surface of the IGBT region 10 are flush, and the second main surface of the diode region 20 and the second main surface of the IGBT region 10 are flush.

As illustrated in FIG. 11, also in the diode region 20, the n-type carrier stored layer 2 is provided on the first main surface side of the n⁻-type drift layer 1, and the n-type buffer layer 3 is provided on the second main surface side of the n-type drift layer 1 as in the IGBT region 10. The n-type carrier stored layer 2 and the n-type buffer layer 3 that are provided in the diode region 20 have the same configuration as the n-type carrier stored layer 2 and the n-type buffer layer 3 that are provided in the IGBT region 10. The n-type carrier stored layer 2 is not necessarily provided in the IGBT region 10 and the diode region 20, and the n-type carrier stored layer 2 may not be provided in the diode region 20 even when the n-type carrier stored layer 2 is provided in the IGBT region 10. Similarly to the IGBT region 10, the n-type drift layer 1, the n-type carrier stored layer 2, and the n-type buffer layer 3 may be collectively referred to as a drift layer.

The p-type anode layer 25 is provided on the first main surface side of the n-type carrier stored layer 2. The p-type anode layer 25 is provided between the n⁻-type drift layer 1 and the first main surface. In the p-type anode layer 25, the p-type anode layer 25 and the p-type base layer 15 may be simultaneously formed by making the concentration of the p-type impurity the same as that of the p-type base layer 15 of the IGBT region 10. In addition, the concentration of the p-type impurity of the p-type anode layer 25 may be lower than the concentration of the p-type impurity of the p-type base layer 15 of the IGBT region 10 to reduce an amount of holes implanted into the diode region 20 during diode operation. A recovery loss during the diode operation can be reduced by reducing the amount of holes implanted during the diode operation.

The p⁺-type contact layer 24 is provided on the first main surface side of the p-type anode layer 25. The concentration of the p-type impurity of the p⁺-type contact layer 24 may be the same as or different from the concentration of the p-type impurity of the p⁺-type contact layer 14 of the IGBT region 10. The p⁺-type contact layer 24 configures the first main surface of the semiconductor substrate. When the p⁺-type contact layer 24 is a region having a higher concentration of the p-type impurity than the p-type anode layer 25, and when the p⁺-type contact layer 24 and the p-type anode layer 25 are required to be distinguished from each other, they may be referred to individually, and the p⁺-type contact layer 24 and the p-type anode layer 25 may be collectively referred to as a p-type anode layer.

In the diode region 20, the n⁺-type cathode layer 26 is provided on the second main surface side of the n-type buffer layer 3. The n⁺-type cathode layer 26 is provided between the n-type drift layer 1 and the second main surface. The n⁺-type cathode layer 26 is a semiconductor layer containing, for example, arsenic or phosphorus as the n-type impurity, and the concentration of the n-type impurity is 1.0E+16/cm³ to 1.0E+21/cm³. As illustrated in FIG. 3, the n⁺-type cathode layer 26 is provided in a part or all of the diode region 20. The n⁺-type cathode layer 26 configures the second main surface of the semiconductor substrate. Although not illustrated, the p-type impurity may be further selectively implanted into the region where the n⁺-type cathode layer 26 is formed as described above, and the p-type cathode layer may be provided using a part of the region where the n⁺-type cathode layer 26 is formed as the p-type semiconductor.

As illustrated in FIG. 11, trenches each penetrating the p-type anode layer 25 from the first main surface of the semiconductor substrate and reaching the n⁻-type drift layer 1 are formed in the diode region 20 of the semiconductor device 100. The diode trench electrode 21a is provided in the trench of the diode region 20 through the diode trench insulating film 21b to configure the diode trench gate 21. The diode trench electrode 21a is opposite to the n⁻-type drift layer 1 through the diode trench insulating film 21b.

As illustrated in FIG. 11, the barrier metal 5 is provided on the diode trench electrode 21a and the p⁺-type contact layer 24. The barrier metal 5 is in ohmic contact with the diode trench electrode 21a and the p⁺-type contact layer 24, and is electrically connected to the diode trench electrode and the p⁺-type contact layer 24. The barrier metal 5 may have the same configuration as the barrier metal 5 in the IGBT region 10. An emitter electrode 6 is provided on the barrier metal 5. The emitter electrode 6 provided in the diode region 20 is formed continuously with the emitter electrode 6 provided in the IGBT region 10. Similarly to the IGBT region 10, the diode trench electrode 21a and the p⁺-type contact layer 24 may be brought into ohmic contact with the emitter electrode 6 without providing the barrier metal 5. Although FIG. 11 illustrates a view in which the interlayer insulating film 4 is not provided on the diode trench electrode 21a of the diode trench gate 21, the interlayer insulating film 4 may be formed on the diode trench electrode 21a of the diode trench gate 21. When the interlayer insulating film 4 is formed on the diode trench electrode 21a of the diode trench gate 21, the emitter electrode 6 and the diode trench electrode 21a may be electrically connected to each other in another section.

The collector electrode 7 is provided on the second main surface side of the n⁺-type cathode layer 26. Similarly to the emitter electrode 6, the collector electrode 7 of the diode region 20 is formed continuously with the collector electrode 7 provided in the IGBT region 10. The collector electrode 7 is in ohmic contact with the n⁺-type cathode layer 26 and is electrically connected to the n⁺-type cathode layer 26.

FIG. 12 is the cross-sectional view of the semiconductor device 100 taken along the broken line D-D of FIG. 10, and is a cross-sectional view of the diode region 20. Differences from the cross-sectional view taken along the broken line C-C illustrated in FIG. 11 are that the p⁺-type contact layer 24 is not provided between the p-type anode layer 25 and the barrier metal 5 and that the p-type anode layer 25 configures the first main surface of the semiconductor substrate. That is, the p⁺-type contact layer 24 in FIG. 11 is selectively provided on the first main surface side of the p-type anode layer 25.

### (7) Structure of Diode Region 20 According to Present Preferred Embodiment

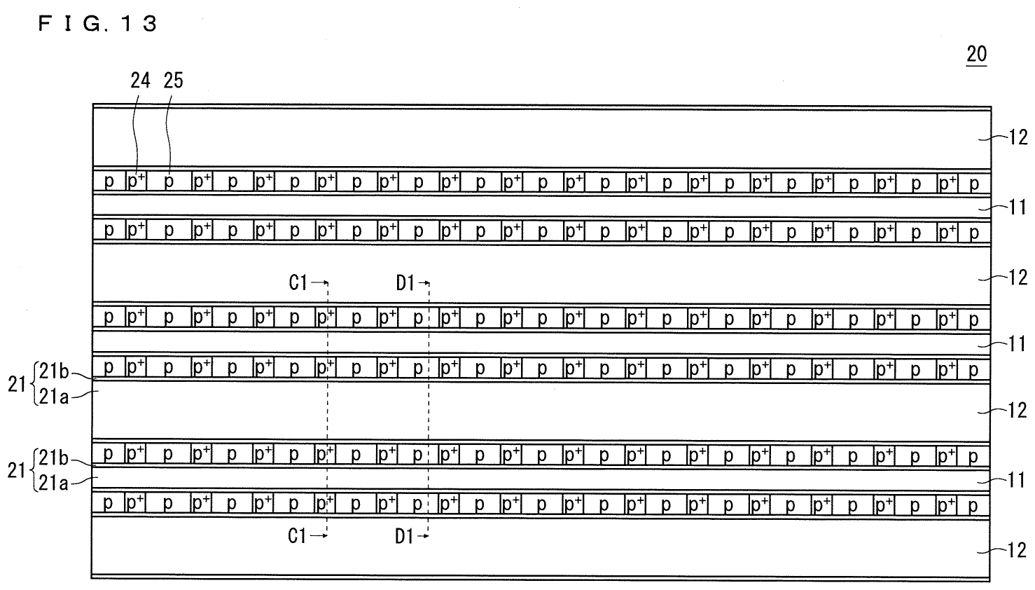

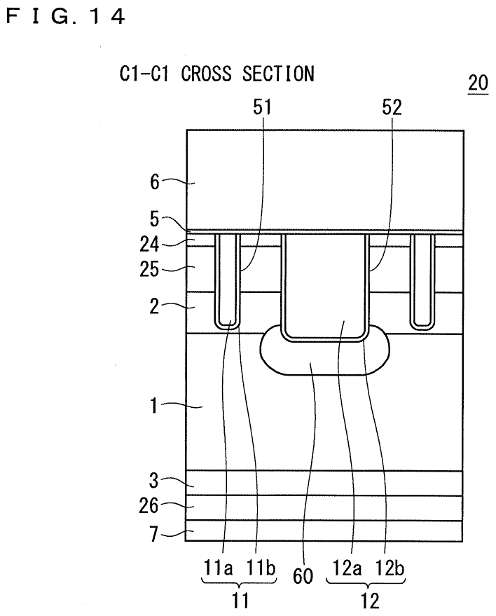

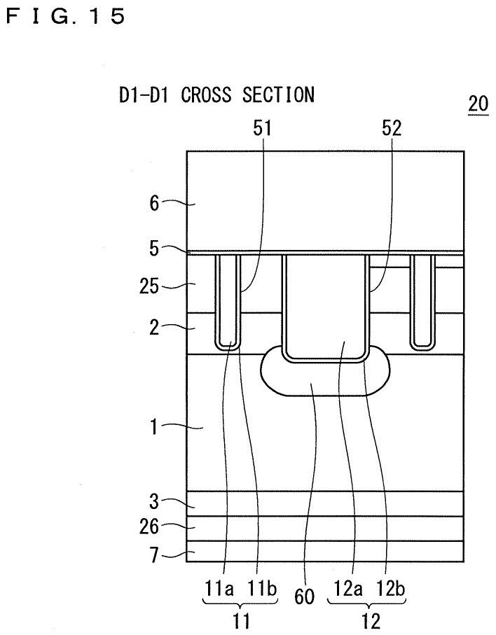

FIGS. 13 to 15 are views each illustrating a structure of the diode region 20 of the semiconductor device 100 according to the first preferred embodiment. FIG. 13 is an enlarged plan view of a part of the diode region 20. FIGS. 14 and 15 are cross-sectional views each illustrating a configuration of a diode disposed in the diode region 20. FIG. 13 is an enlarged view illustrating a region surrounded by the broken line 83 in the semiconductor device 100 illustrated in FIG. 2 or 3. FIG. 14 is a cross-sectional view taken along a broken line C1-C1 illustrated in FIG. 13, and FIG. 15 is a cross-sectional view taken along a broken line D1-D1 illustrated in FIG. 13.

As illustrated in FIGS. 13 to 15, in the semiconductor device 100 according to the first preferred embodiment, the first trenches 51 and the second trenches 52 having different widths are disposed also in the diode region 20. The width of the second trenches 52 is wider than the width of the first trenches 51. The diode trench gate 21 including the diode trench electrode 21a and the diode trench insulating film 21b is formed in both the first trench 51 and the first trench 51.

As illustrated in FIGS. 14 and 15, a depth of the second trench 52 is deeper than a depth of the first trench 51 in a first direction (downward direction on drawing), and the width of the second trench 52 is wider than the width of the first trench 51 in a second direction (lateral direction on the drawing). In addition, a p-type bottom layer 60 is formed at a bottom of the second trench 52 so as to be in contact with the second trench 52. The p-type bottom layer 60 exhibits the electric field relaxation effect also in the diode region 20. The p-type bottom layer 60 is not formed at a bottom of the first trench 51. In addition, the p-type bottom layer 60 at the bottom of the second trench 52 is formed so as not to be in contact with the first trench 51.

Since the second trenches 52 are deeper than the first trenches 51, a distance between the bottoms of the second trenches 52 in which the p-type bottom layers 60 are provided becomes long, so that the adjacent p-type bottom layers 60 are prevented from being connected, and the p-type bottom layers 60 are prevented from shielding a gap between trenches. Therefore, the p-type bottom layers 60 can be formed deeper. In addition, since the widths of the second trenches 52 are wide, regions occupied by the p-type bottom layers 60 can be increased, and an electric field relaxation effect by the p-type bottom layers 60 can be enhanced.

Although the first trenches 51 and the second trenches 52 are alternately arranged one by one in FIG. 13, the diode region 20 may have a region in which the plurality of first trenches 51 are continuously disposed side by side and a region in which the plurality of second trenches 52 are continuously disposed side by side. That is, it is not necessary that all the first trenches 51 are adjacent to the second trenches 52, and it is sufficient that at least some of the first trenches 51 are adjacent to the second trenches 52. Similarly, it is not necessary that all the second trenches 52 are adjacent to the first trenches 51, and it is sufficient that at least some of the second trenches 52 are adjacent to the first trenches 51.

A ratio of the regions where the p-type bottom layers 60 are disposed in the diode region 20 and a ratio of the regions where the p-type bottom layers 60 are disposed in the IGBT region 10 may be different from each other.

Although FIGS. 14 and 15 illustrate the example in which the n-type carrier stored layer 2 is formed in the diode region 20, the n-type carrier stored layer 2 is not necessarily provided in the diode region 20.

### (8) Boundary Region Between IGBT Region 10 and Diode Region 20

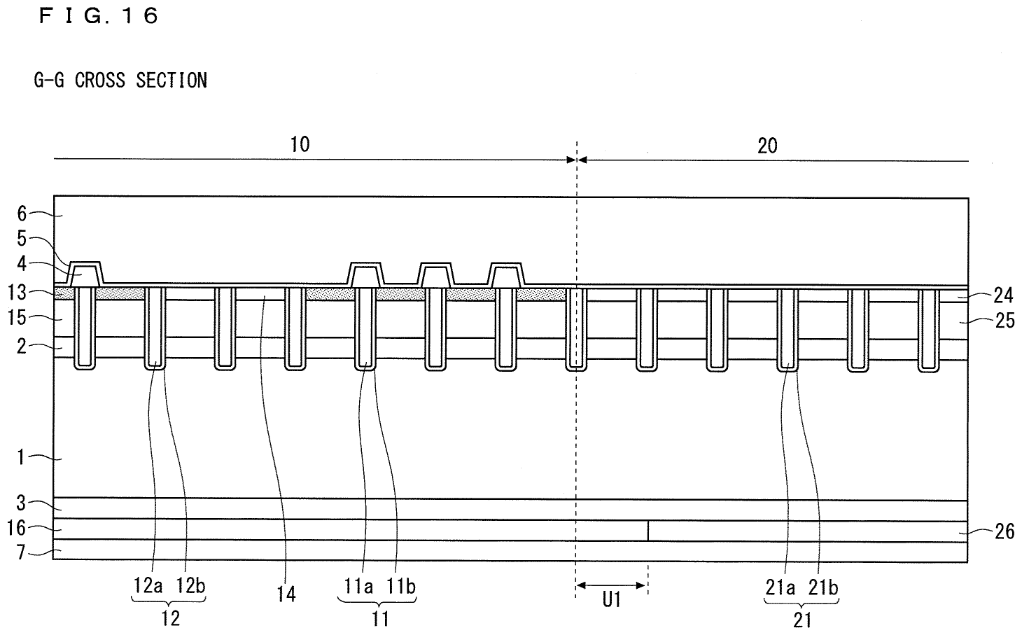

FIG. 16 is a cross-sectional view illustrating a configuration of a boundary between an IGBT region and a diode region of a semiconductor device that is an RC-IGBT. FIG. 16 is a cross-sectional view taken along a broken line G-G in the semiconductor device 100 illustrated in FIG. 2.

As illustrated in FIG. 16, the p-type collector layer 16 provided on the second main surface side of the IGBT region 10 is provided so as to protrude from the boundary between the IGBT region 10 and the diode region 20 toward the diode region 20 side by a distance U1. As described above, when the p-type collector layer 16 is provided so as to protrude to the diode region 20, a distance between the n⁺-type cathode layer 26 of the diode region 20 and the active trench gate 11 can be increased, and even when the gate drive voltage is applied to the gate trench electrode 11a during freewheeling diode operation, the current can be prevented from flowing from a channel formed adjacent to the active trench gate 11 of the IGBT region 10 to the n⁺-type cathode layer 26. For example, the distance U1 may be 100 μm. Note that the distance U1 may be zero or a distance smaller than 100 μm depending on the application of the semiconductor device 100 that is the RC-IGBT.

### (9) Example of Structure of Termination Region 30

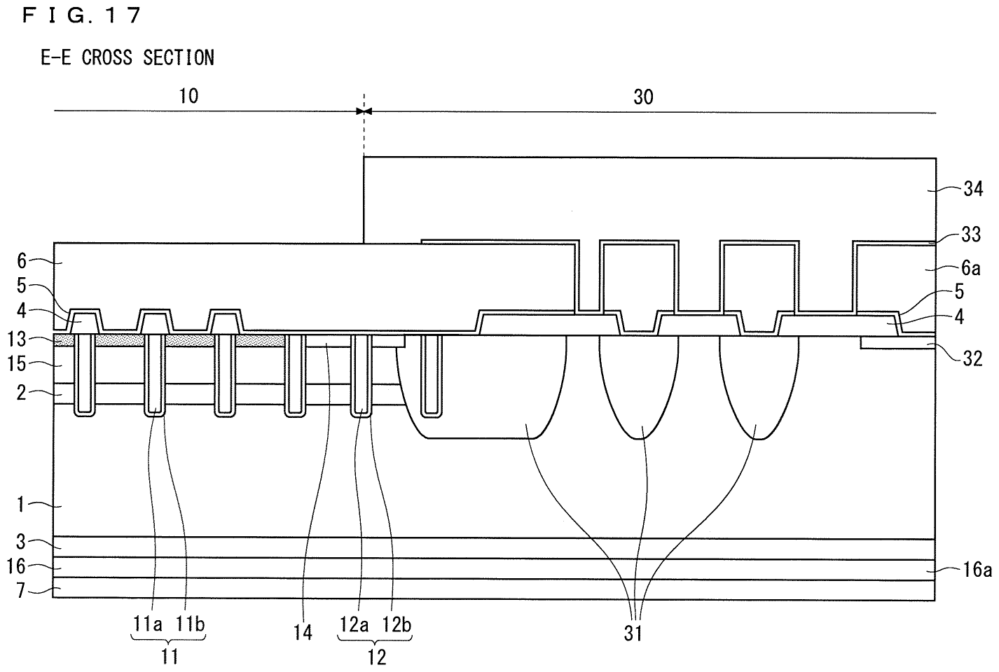

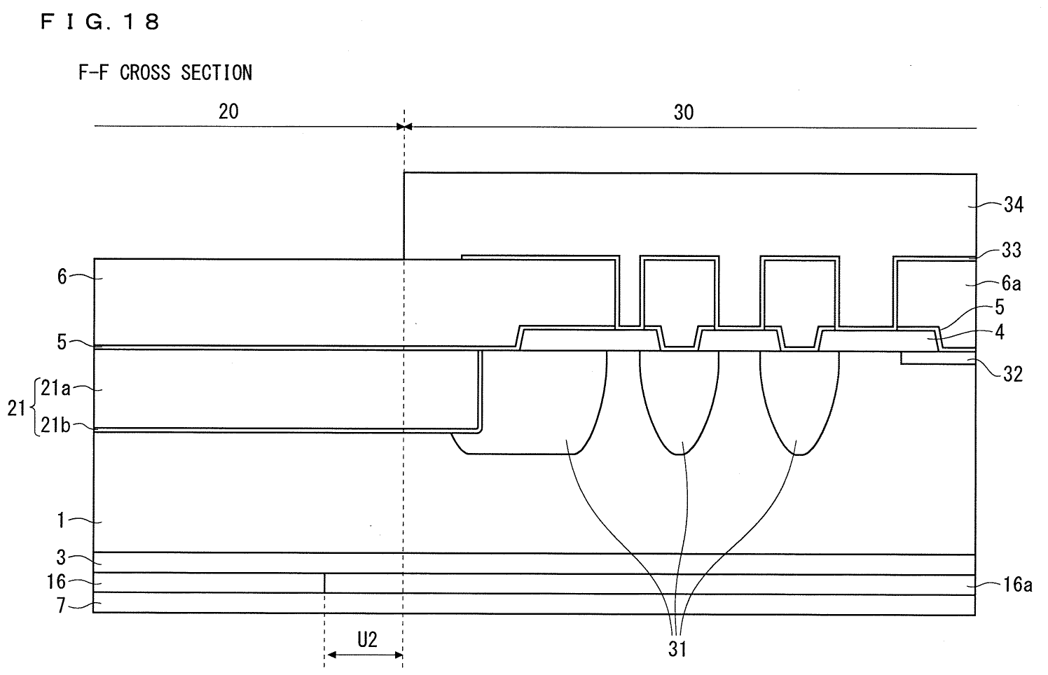

FIGS. 17 and 18 are cross-sectional views each illustrating a configuration of a termination region of a semiconductor device that is an RC-IGBT. FIG. 17 is a cross-sectional view taken along a broken line E-E of FIG. 2 or 3, and is a cross-sectional view from the IGBT region 10 to the termination region 30. FIG. 18 is a cross-sectional view taken along a broken line F-F of FIG. 2, and is a cross-sectional view from the diode region 20 to the termination region 30.

As illustrated in FIGS. 17 and 18, the termination region 30 of the semiconductor device 100 includes the n⁻-type drift layer 1 between the first main surface and the second main surface of the semiconductor substrate. The first main surface and the second main surface of the termination region 30 are flush with the first main surfaces and the second main surfaces of the IGBT region 10 and the diode region 20, respectively. The n⁻-type drift layer 1 of the termination region 30 has the same configuration as the n-type drift layer 1 of the IGBT region 10 and the diode region 20, and is continuously and integrally formed.

A p-type termination well layer 31 is provided on the first main surface side of the n⁻-type drift layer 1, namely, between the first main surface of the semiconductor substrate and the n⁻-type drift layer 1. The p-type termination well layer 31 is a semiconductor layer containing, for example, boron or aluminum as the p-type impurity, and the concentration of the p-type impurity is 1.0E+14/cm³ to 1.0E+19/cm³. The p-type termination well layer 31 is provided so as to surround the cell region including the IGBT region 10 and the diode region 20. A plurality of the p-type termination well layers 31 are provided in a ring shape, and the number of the provided p-type termination well layers 31 is appropriately selected according to the withstand voltage design of the semiconductor device 100. Furthermore, an n⁺-type channel stopper layer 32 is provided on a further outer edge side of the p-type termination well layer 31, and the n⁺-type channel stopper layer 32 surrounds the p-type termination well layer 31.

The p-type termination collector layer 16a is provided between the n-type drift layer 1 and the second main surface of the semiconductor substrate. The p-type termination collector layer 16a is formed integrally and continuously with the p-type collector layer 16 provided in the cell region. Accordingly, the p-type termination collector layer 16a may be referred to as the p-type collector layer 16. In the configuration in which the diode region 20 is provided adjacent to the termination region 30 as in the semiconductor device 100 illustrated in FIG. 2, the p-type termination collector layer 16a is provided such that an end portion on the diode region 20 side protrudes to the diode region 20 by a distance U2 as illustrated in FIG. 18. As described above, when the p-type termination collector layer 16a is provided so as to protrude to the diode region 20, the distance between the n⁺-type cathode layer 26 of the diode region 20 and the p-type termination well layer 31 can be increased, and the p-type termination well layer 31 can be prevented from operating as an anode of the diode. For example, the distance U2 may be 100 μm.

The collector electrode 7 is provided on the second main surface of the semiconductor substrate. The collector electrode 7 is integrally formed continuously from the cell region including the IGBT region 10 and the diode region 20 to the termination region 30. On the other hand, the emitter electrode 6 continuous from the cell region and a termination electrode 6a separated from the emitter electrode 6 are provided on the first main surface of the semiconductor substrate in the termination region 30.

The emitter electrode 6 and the termination electrode 6a are electrically connected through a semi-insulating film 33. For example, the semi-insulating film 33 may be a semi-insulating silicon nitride (sinSiN) film. The termination electrode 6a, the p-type termination well layer 31, and the n⁺-type channel stopper layer 32 are electrically connected through the contact hole made in the interlayer insulating film 4 provided on the first main surface of the termination region 30. In addition, in the termination region 30, a termination protection film 34 is provided so as to cover the emitter electrode 6, the termination electrode 6a, and the semi-insulating film 33. For example, the termination protection film 34 may be formed of polyimide.

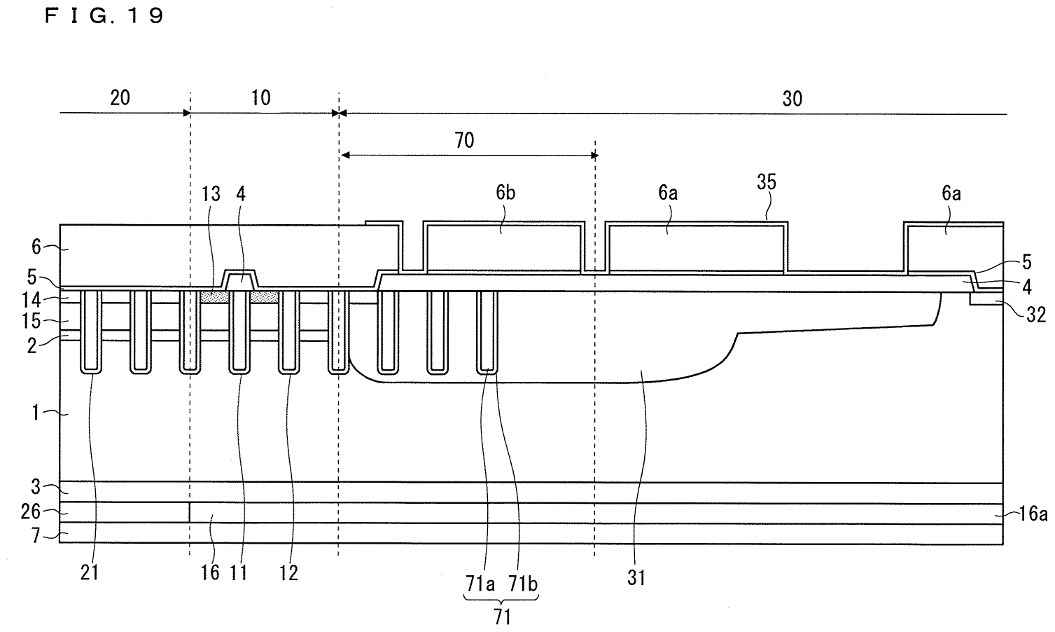

FIG. 19 is a cross-sectional view illustrating another example of the configuration of the termination region of the semiconductor device that is the RC-IGBT, and illustrates a cross section over the diode region 20, the IGBT region 10, and the termination region 30. A wiring region 70 is provided in a portion on the inner peripheral side of the termination region 30. Although the wiring region 70 is included in the termination region 30 here, the wiring region 70 and the termination region 30 may be defined as separate regions.

In the wiring region 70, for example, a wiring electrode 6b such as a gate wiring is disposed. The termination electrode 6a in the termination region 30 and the wiring electrode 6b in the wiring region 70 are covered with a protective insulating film 35.

In the semiconductor substrate of the termination region 30, the p-type termination well layer 31 is formed on the first main surface side of the n⁻-type drift layer 1. In the example of FIG. 19, the p-type termination well layer 31 has a VLD structure.

A plurality of trenches are provided in the wiring region 70, which is the portion on the inner peripheral side of the termination region 30, as in the IGBT region 10 and the diode region 20. Here, a trench on the outermost side among the trenches provided in the termination region 30 is defined as an “outermost trench”. An outermost trench gate 71 having the same configuration as the active trench gate 11 and the dummy trench gate 12 is formed in the outermost trench. That is, the outermost trench gate 71 includes an insulating film (outermost trench insulating film 71b) formed on an inner surface of the outermost trench and an electrode (outermost trench electrode 71a) formed on the insulating film.

In the semiconductor device of the trench gate type, an electric field tends to concentrate on the vicinity of a bottom of the outermost trench gate 71, and one of objects is to relax the electric field in such a portion. In the example of FIG. 19, a depth of the p-type termination well layer 31 is deeper than a depth of the trench, and the bottom of the outermost trench gate 71 is covered with the p-type termination well layer 31. As a result, the electric field in the vicinity of the bottom of the outermost trench gate 71 is relaxed.

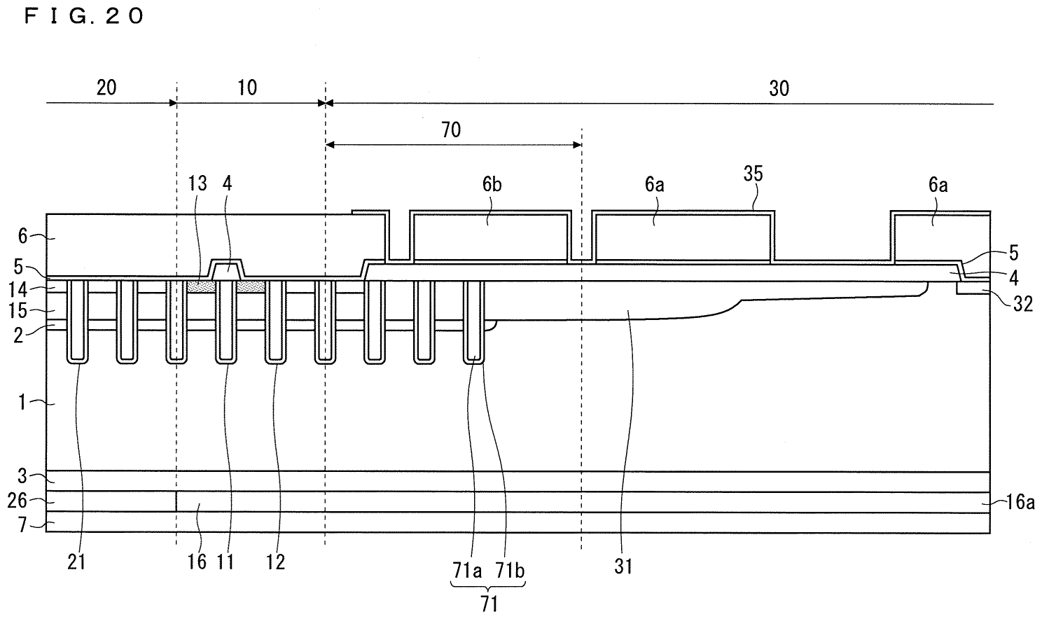

In FIG. 20, the p-type termination well layer 31 is formed to be shallower than trenches as compared with the configuration in FIG. 19. In this case, a bottom of the outermost trench gate 71 is not covered with the p-type termination well layer 31, and thus an electric field in the vicinity of a bottom of the outermost trench gate 71 tends to increase.

### (10) Structure of Termination Region 30 of Present Preferred Embodiment

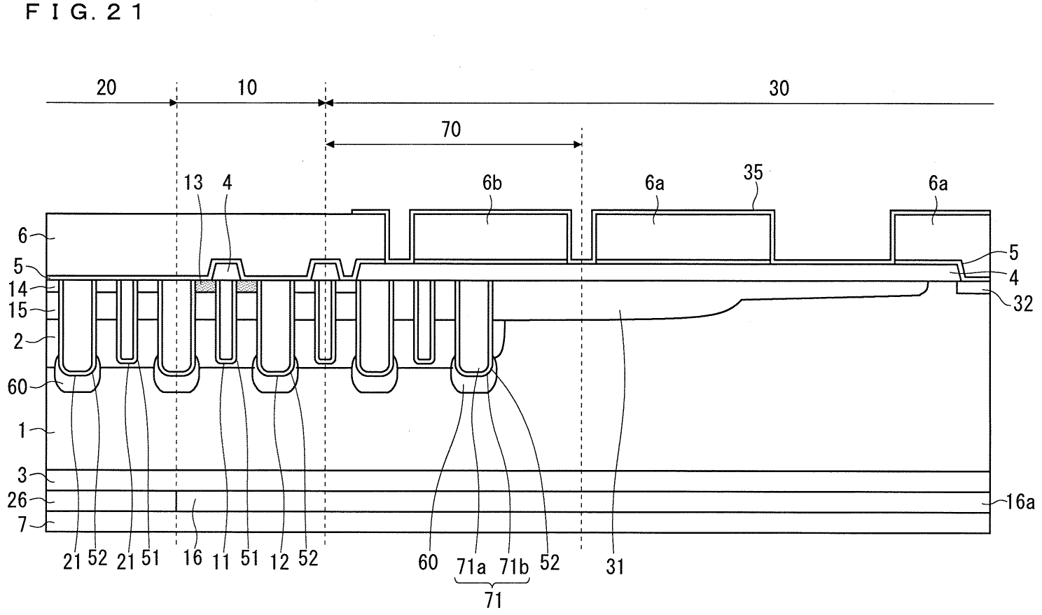

FIG. 21 is a cross-sectional view illustrating a structure of the termination region 30 of the semiconductor device according to the present preferred embodiment. As illustrated in FIG. 21, in the present preferred embodiment, the first trenches 51 and the second trenches 52 are provided in the wiring region 70, which is the portion on the inner peripheral side of the termination region 30 (boundary portion between the cell region and the termination region 30), as in the IGBT region 10 and the diode region 20. The outermost trench gate 71 is disposed in the second trench 52. The p-type bottom layer 60 in contact with the bottom of the second trench 52 is provided under the second trench 52 in which the outermost trench gate 71 is disposed.

In the present preferred embodiment, the bottom of the p-type termination well layer 31 is shallower than the bottom of the second trench 52 in which the outermost trench gate 71 is disposed. Therefore, the bottom of the outermost trench gate 71 is not covered with the p-type termination well layer 31.

According to the configuration of FIG. 21, the p-type bottom layer 60 under the outermost trench can relax the electric field in the vicinity of the bottom of the outermost trench gate 71. Therefore, even if the bottom of the p-type termination well layer 31 is made shallower than the bottom of the outermost trench, the electric field in the vicinity of the bottom of the outermost trench gate 71 is prevented from increasing.

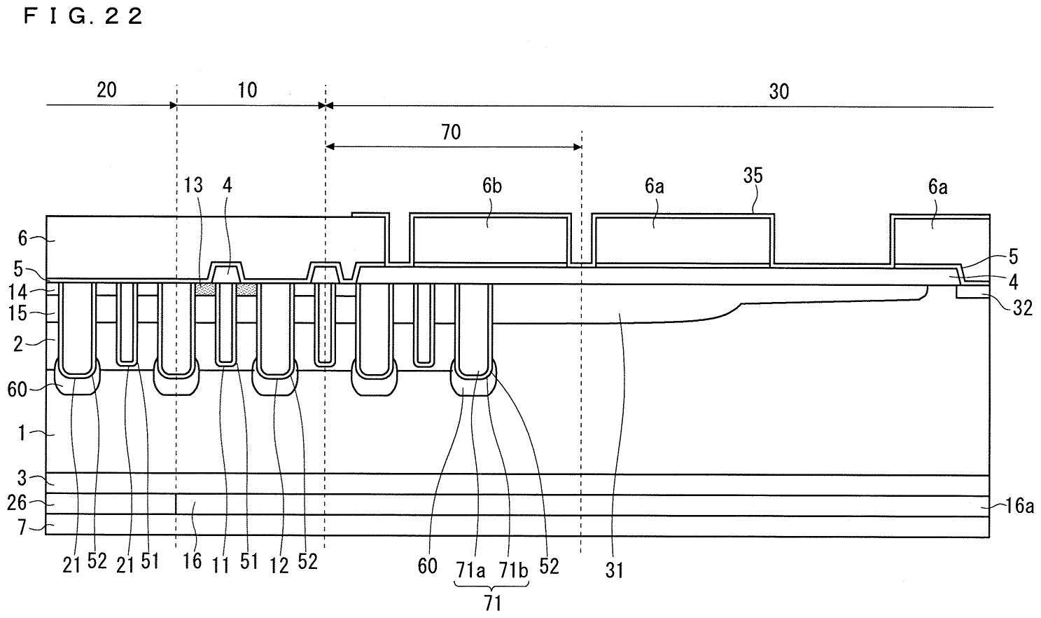

Although the outermost end of the n-type carrier stored layer 2 is located on the outer side (right side on the drawing) of the outermost trench gate 71 in FIG. 21, the outermost end of the n-type carrier stored layer 2 may be located on the inner side (left side on the drawing) of the outermost trench gate 71 as in FIG. 22.

In addition, a plurality of the outermost trench gates 71 each having the p-type bottom layer 60 at the bottom may be continuously disposed. That is, among the trenches provided in the termination region 30, a plurality of trenches arranged on the outermost side may be defined as “outermost trenches”, and the outermost trench gate 71 and the p-type bottom layer 60 may be provided in each of the plurality of outermost trenches. If an interval between the plurality of outermost trench gates 71 is gradually increased toward the outer side, the electric field relaxation effect is further improved. The plurality of outermost trench gates 71 may be provided only in some trenches of the termination region 30 or may be provided in all the trenches of the termination region 30.

### (11) Example of Method of Manufacturing IGBT and RC-IGBT

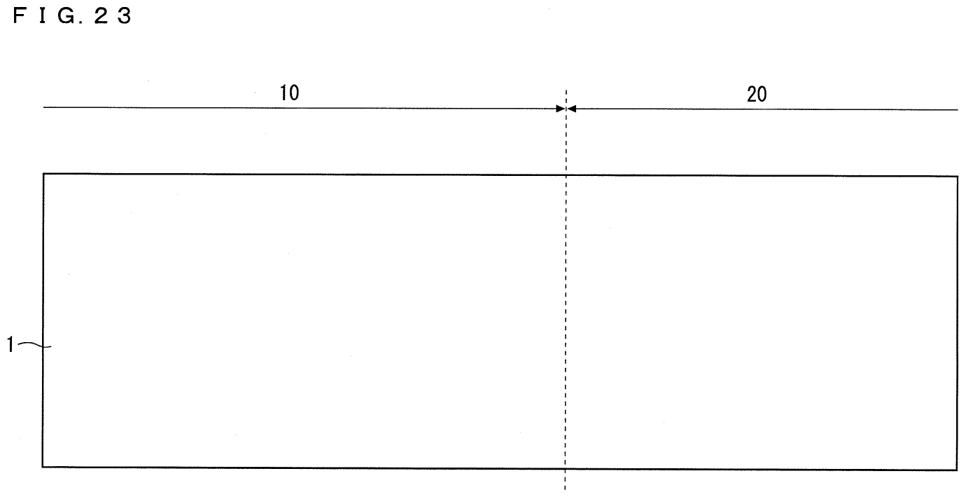

FIGS. 23 to 34 are views illustrating a method of manufacturing a semiconductor device that is an RC-IGBT. A method of manufacturing an IGBT is obtained by extracting a process of manufacturing an IGBT region from the method of manufacturing an RC-IGBT. That is, since the method of manufacturing an IGBT is substantially included in the method of manufacturing an RC-IGBT, the method of manufacturing an RC-IGBT will be described here.

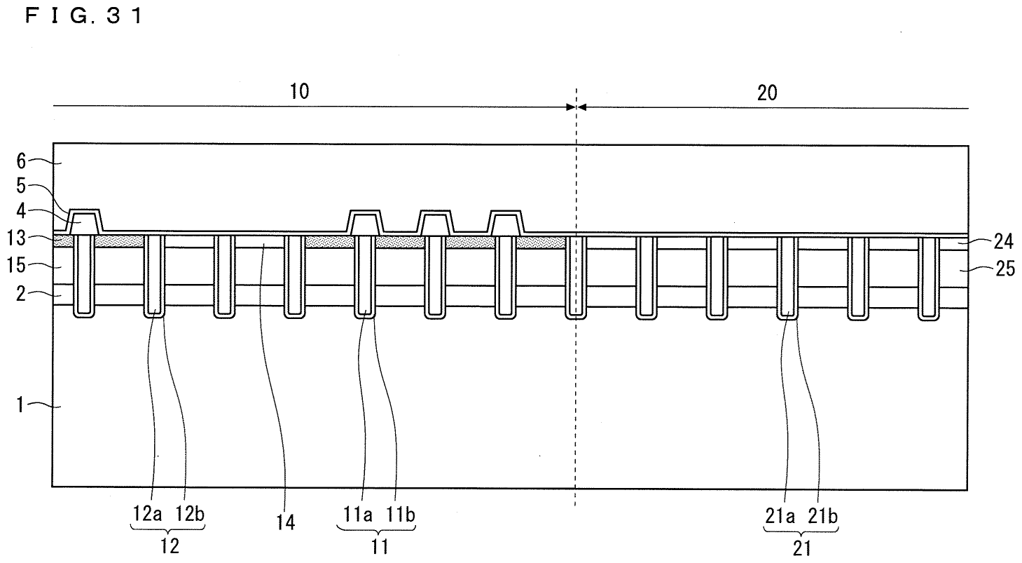

FIGS. 23 to 30 are views illustrating a process of forming a front surface side of the semiconductor device 100, and FIGS. 31 to 34 are views illustrating a process of forming a back surface side of the semiconductor device 100.

First, as illustrated in FIG. 23, a semiconductor substrate configuring the n⁻-type drift layer 1 is prepared. The semiconductor substrate may be, for example, a so-called floating zone (FZ) wafer manufactured by an FZ method, a so-called magnetic field applied CZochralski (MCZ) wafer manufactured by an MCZ method, or an n-type wafer containing an n-type impurity. The concentration of the n-type impurity contained in the semiconductor substrate is appropriately selected depending on the withstand voltage of the semiconductor device to be manufactured. For example, in the semiconductor device having the withstand voltage of 1200 V, the concentration of the n-type impurity is adjusted such that specific resistance of the n⁻-type drift layer 1 configuring the semiconductor substrate is about 40 Ω·cm to about 120 Ω·cm. As illustrated in FIG. 23, the entire semiconductor substrate is the n⁻-type drift layer 1 in the process of preparing the semiconductor substrate, and a p-type or n-type impurity ion is implanted from a first main surface side or a second main surface side of the semiconductor substrate, and then diffused into the semiconductor substrate by heat treatment or the like, thereby forming a p-type or n-type semiconductor layer to manufacture the semiconductor device 100.

As illustrated in FIG. 23, the semiconductor substrate configuring the n⁻-type drift layer 1 includes a region that becomes the IGBT region 10 and the diode region 20. Although not illustrated, a region that becomes the termination region 30 is provided around the region that becomes the IGBT region 10 and the diode region 20. Although a method of manufacturing configurations of the IGBT region 10 and the diode region 20 of the semiconductor device 100 will be mainly described hereinafter, the termination region 30 of the semiconductor device 100 may be manufactured by a known manufacturing method. For example, when the FLR including the p-type termination well layer 31 as the withstand voltage holding structure is formed in the termination region 30, the FLR may be formed by implanting the p-type impurity ion before the IGBT region 10 and the diode region 20 of the semiconductor device 100 are processed, or may be formed by simultaneously implanting the p-type impurity ions during the implantation of the p-type impurity into the IGBT region 10 or the diode region 20 of the semiconductor device 100.

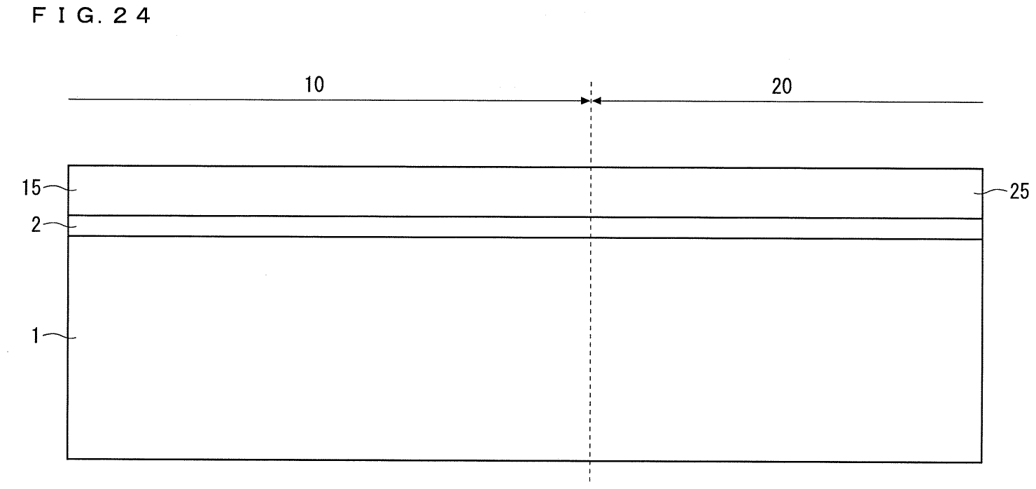

Next, as illustrated in FIG. 24, the n-type impurity such as phosphorus (P) is implanted from the first main surface side of the semiconductor substrate to form the n-type carrier stored layer 2. In addition, the p-type impurity such as boron (B) is implanted from the first main surface side of the semiconductor substrate to form the p-type base layer 15 and the p-type anode layer 25. The n-type carrier stored layer 2, the p-type base layer 15 and the p-type anode layer 25 are formed by implanting the impurity ions into the semiconductor substrate and then diffusing the impurity ions by heat treatment. The n-type impurity and the p-type impurity are ion-implanted after mask processing is performed on the first main surface of the semiconductor substrate, so that the n-type impurity and the p-type impurity are selectively formed on the first main surface side of the semiconductor substrate. The n-type carrier stored layer 2, the p-type base layer 15, and the p-type anode layer 25 are formed in the IGBT region 10 and the diode region 20, and are connected to the p-type termination well layer 31 at the termination region 30. The mask processing refers to processing for applying a resist on the semiconductor substrate, forming an opening in a predetermined region of the resist using a photolithography technique, and forming a mask on the semiconductor substrate in order to perform the ion implantation or etching on the predetermined region of the semiconductor substrate through the opening.

The p-type base layer 15 and the p-type anode layer 25 may be formed by simultaneous ion implantation of the p-type impurity. In this case, depths or p-type impurity concentrations of the p-type base layer 15 and the p-type anode layer 25 are the same and have the same configuration. In addition, the depths or the p-type impurity concentrations of the p-type base layer 15 and the p-type anode layer 25 may be made different by separately ion-implanting the p-type impurity into the p-type base layer 15 and the p-type anode layer 25 by the mask processing.

The p-type termination well layer 31 formed in another section may be formed by ion-implanting the p-type impurity simultaneously with the p-type anode layer 25. In this case, the depths or the p-type impurity concentrations of the p-type termination well layer 31 and the p-type anode layer 25 are the same, and can have the same configuration. In addition, the p-type termination well layer 31 and the p-type anode layer 25 can be formed by the simultaneous ion implantation of the p-type impurity, and the p-type impurity of the p-type termination well layer 31 and the p-type anode layer 25 can be set to different concentrations. In this case, one or both of the masks may be used as a mesh-like mask to change an aperture ratio.

In addition, the depths or the p-type impurity concentrations of the p-type termination well layer 31 and the p-type anode layer 25 may be made different by separately ion-implanting the p-type impurity into the p-type termination well layer 31 and the p-type anode layer 25 by the mask processing. The p-type termination well layer 31, the p-type base layer 15, and the p-type anode layer 25 may be formed by the simultaneous ion implantation of the p-type impurity.

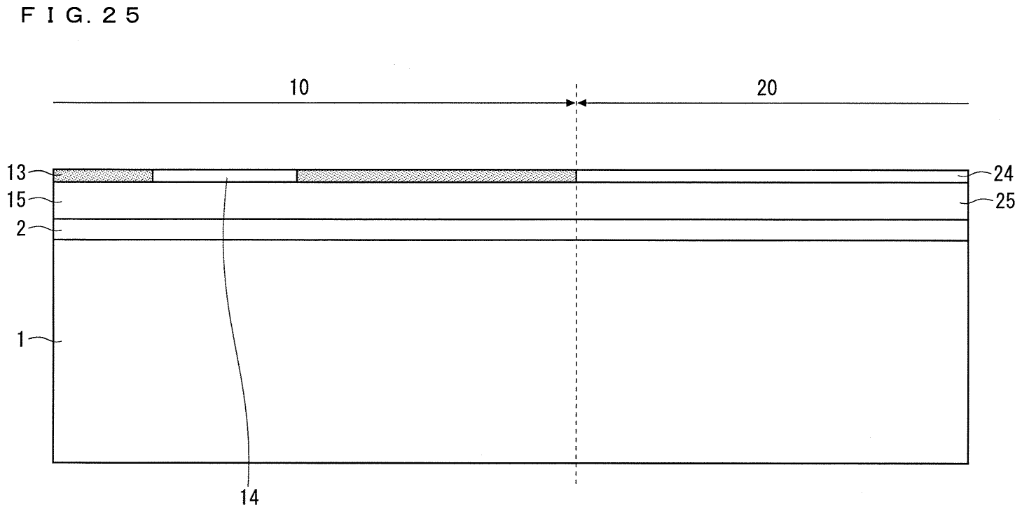

Next, as illustrated in FIG. 25, the n-type impurity is selectively implanted into the first main surface side of the p-type base layer 15 of the IGBT region 10 by the mask processing to form the n⁺-type emitter layer 13. For example, the implanted n-type impurity is arsenic (As) or phosphorus (P). In addition, by the mask processing, the p-type impurity is selectively implanted into the first main surface side of the p-type base layer 15 of the IGBT region 10 to form the p⁺-type contact layer 14, and the p-type impurity is selectively implanted into the first main surface side of the p-type anode layer 25 of the diode region 20 to form the p⁺-type contact layer 24. For example, the implanted p-type impurity is boron (B) or aluminum (Al).

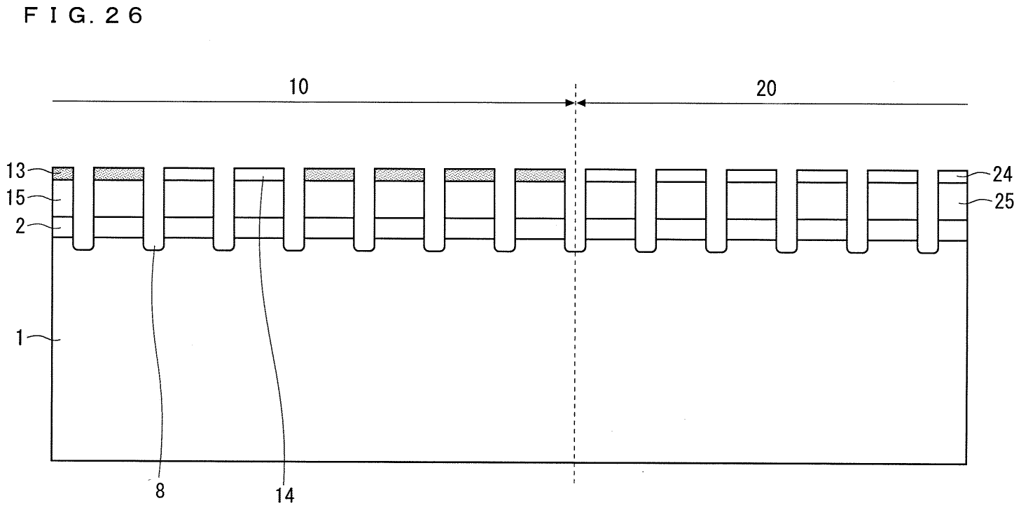

Next, as illustrated in FIG. 26, trenches 8 each penetrating the p-type base layer 15 and the p-type anode layer 25 from the first main surface side of the semiconductor substrate and reaching the n⁻-type drift layer 1 are formed. In the IGBT region 10, a side wall of the trench 8 penetrating the n⁺-type emitter layer 13 configures a part of the n⁺-type emitter layer 13. After an oxide film such as SiO₂ is deposited on the semiconductor substrate, the opening is formed in the oxide film at a portion where the trench 8 is formed by the mask processing, and the semiconductor substrate is formed using the oxide film having the opening as a mask, whereby the trench 8 may be formed. Although the trenches 8 having the same pitch are formed in the IGBT region 10 and the diode region 20 in FIG. 26, the trenches 8 may be formed at different pitches between the IGBT region 10 and the diode region 20. The pitch of the trenches 8 can be appropriately changed depending on the mask pattern of the mask processing in planar view.

Note that the process of forming the trenches 8 may be performed before the process of forming the n⁺-type emitter layer 13 and the p⁺-type contact layer 14.

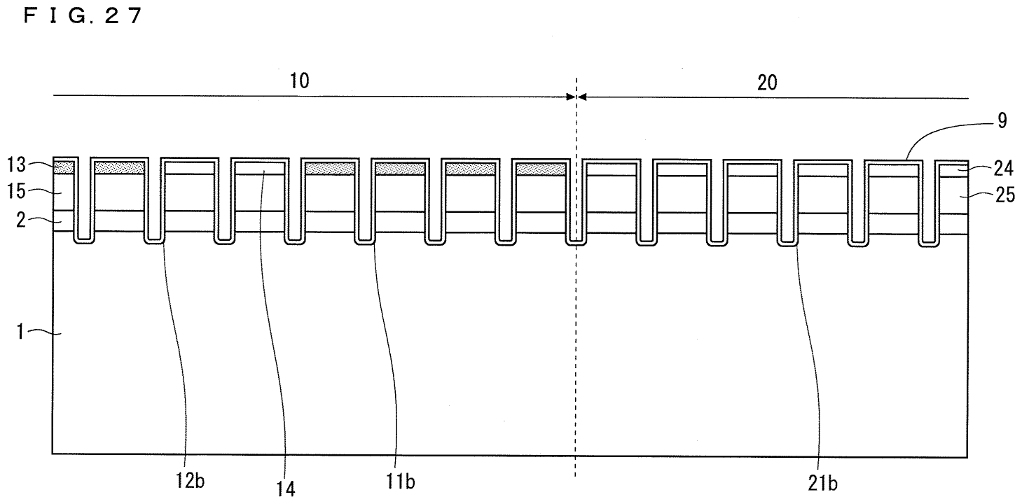

Next, as illustrated in FIG. 27, the semiconductor substrate is heated in an atmosphere containing oxygen to form an oxide film 9 on inner walls of the trenches 8 and the first main surface of the semiconductor substrate. In the oxide film 9 formed on the inner wall of the trench 8, the oxide film 9 formed on the trench 8 of the IGBT region 10 is the gate trench insulating film 11b of the active trench gate 11 and the dummy trench insulating film 12b of the dummy trench gate 12. The oxide film 9 formed in the trench 8 of the diode region 20 is the diode trench insulating film 21b. The oxide film 9 formed on the first main surface of the semiconductor substrate is removed in a later process.

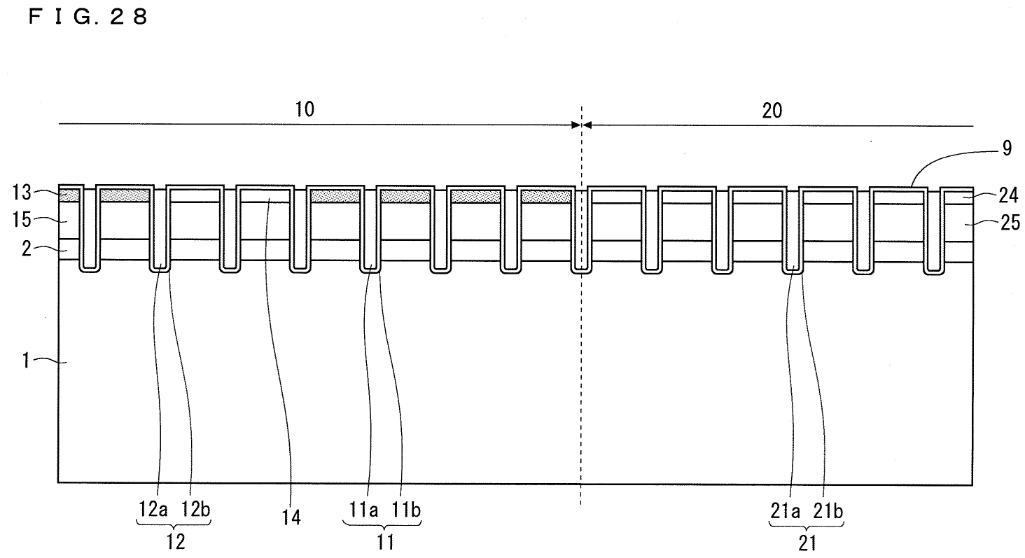

Next, as illustrated in FIG. 28, polysilicon doped with an n-type or p-type impurity by chemical vapor deposition (CVD) or the like is deposited in the trench 8 in which the oxide film 9 is formed on the inner wall, thereby forming the gate trench electrode 11a, the dummy trench electrode 12a, and the diode trench electrode 21a.

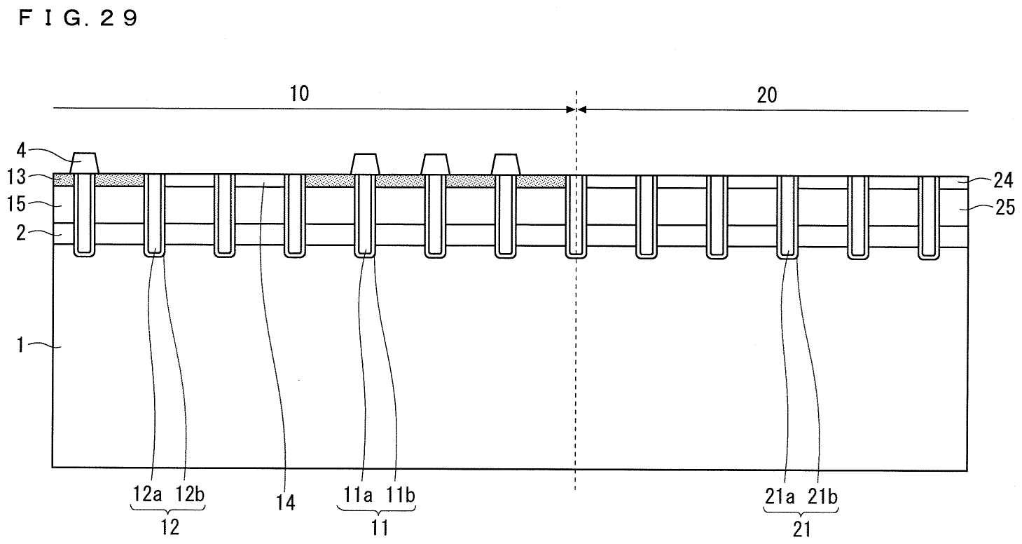

Next, as illustrated in FIG. 29, after the interlayer insulating film 4 is formed on the gate trench electrode 11a of the active trench gate 11 of the IGBT region 10, the oxide film 9 formed on the first main surface of the semiconductor substrate is removed. For example, the interlayer insulating film 4 may be SiO₂. Then, the contact hole is made in the interlayer insulating film 4 deposited by the mask processing. The contact holes are made on the n⁺-type emitter layer 13, the p⁺-type contact layer 14, the p⁺-type contact layer 24, the dummy trench electrode 12a, and the diode trench electrode 21a.

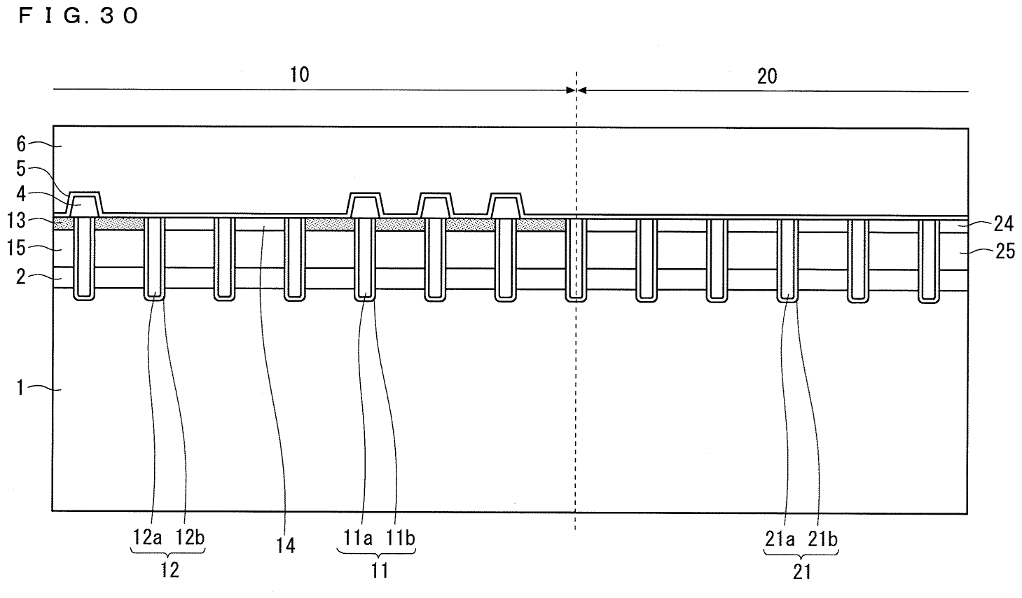

Next, as illustrated in FIG. 30, the barrier metal 5 is formed on the first main surface of the semiconductor substrate and the interlayer insulating film as a single layer or the interlayer insulating film 4 having a multilayer structure including an insulating film, and the emitter electrode 6 is further formed on the barrier metal 5. The barrier metal 5 can be omitted, and is formed by depositing titanium nitride by physical vapor deposition (PVD) or CVD.

For example, the emitter electrode 6 may be formed by depositing an aluminum silicon alloy (Al—Si-based alloy) on the barrier metal 5 by PVD such as sputtering or vapor deposition. A nickel alloy (Ni alloy) may be further formed on the formed aluminum silicon alloy by electroless plating or electrolytic plating to form the emitter electrode 6. When the emitter electrode 6 is formed by plating, a thick metal film can be easily formed as the emitter electrode 6, so that a heat capacity of the emitter electrode 6 can be increased to improve heat resistance. When the nickel alloy is further formed by plating after the emitter electrode 6 made of the aluminum silicon alloy is formed by PVD, the plating treatment may be performed in order to form the nickel alloy after the second main surface side of the semiconductor substrate is processed.

Next, as illustrated in FIG. 31, the second main surface side of the semiconductor substrate is ground to thin the semiconductor substrate to a designed predetermined thickness. For example, the thickness of the ground semiconductor substrate may be 80 μm to 200 μm.

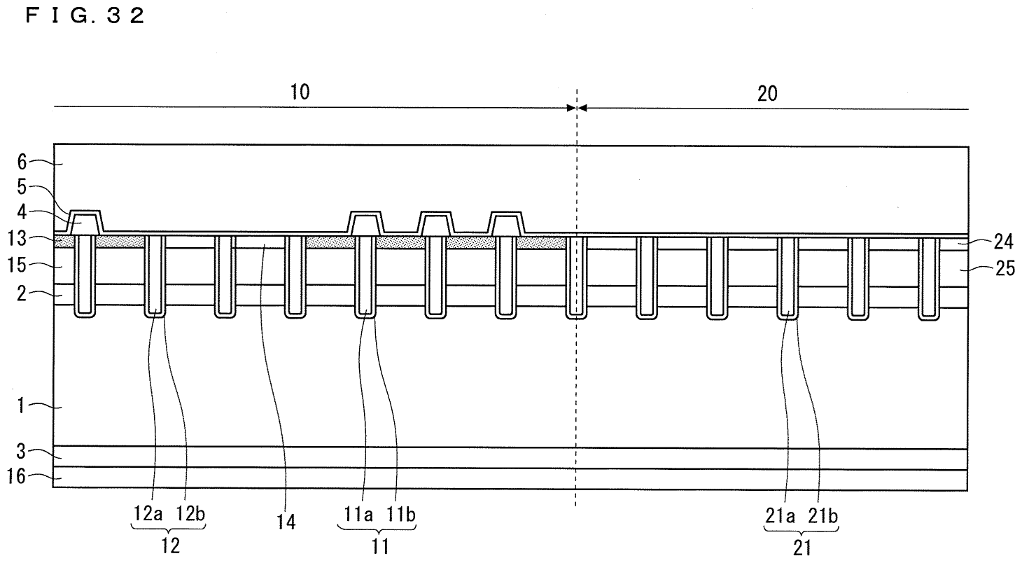

Next, as illustrated in FIG. 32, an n-type impurity is implanted from the second main surface side of the semiconductor substrate to form the n-type buffer layer 3. Furthermore, the p-type impurity is implanted from the second main surface side of the semiconductor substrate to form the p-type collector layer 16. The n-type buffer layer 3 may be formed in the IGBT region 10, the diode region 20, and the termination region 30, or formed only in the IGBT region 10 or the diode region 20.

For example the n-type buffer layer 3 may be formed by implanting a phosphorus (P) ion. In addition, the n-type buffer layer 3 may be formed by implanting a proton (H⁺). Furthermore, both the proton and the phosphorus may be implanted. The proton can be injected from the second main surface of the semiconductor substrate to a deep position with relatively low acceleration energy. In addition, the depth at which the proton is injected can be relatively easily changed by changing the acceleration energy. For this reason, in forming the n-type buffer layer 3 by the proton, when the implantation is performed a plurality of times while the acceleration energy is changed, the n-type buffer layer 3 wider in the thickness direction of the semiconductor substrate than that formed of the phosphorus can be formed.

In addition, the phosphorus can increase an activation rate as the n-type impurity as compared with the proton, so that the punch-through of the depletion layer can be more reliably prevented even in the semiconductor substrate thinned by forming the n-type buffer layer 3 with the phosphorus. In order to further thin the semiconductor substrate, preferably the n-type buffer layer 3 is formed by injecting both the proton and the phosphorus, and in this case, the proton is injected at a position deeper from the second main surface than the phosphorus.

For example, the p-type collector layer 16 is formed by implanting boron (B). The p-type collector layer 16 is also formed in the termination region 30, and the p-type collector layer 16 of the termination region 30 becomes the p-type termination collector layer 16a. After the ion implantation from the second main surface side of the semiconductor substrate, the second main surface is irradiated with laser to perform laser annealing, so that implanted boron is activated to form the p-type collector layer 16. At this time, the phosphorus for the n-type buffer layer 3 injected at a relatively shallow position from the second main surface of the semiconductor substrate is also activated at the same time. On the other hand, the proton is activated at a relatively low annealing temperature such as 350° C. to 500° C., so that attention is required to be paid such that the temperature of the entire semiconductor substrate does not become higher than 350° C. to 500° C. except for the process of activating the proton after injecting the proton. The laser annealing can raise the temperature only in the vicinity of the second main surface of the semiconductor substrate, so that the laser annealing can be used for activating the n-type impurity or the p-type impurity even after the proton is implanted.

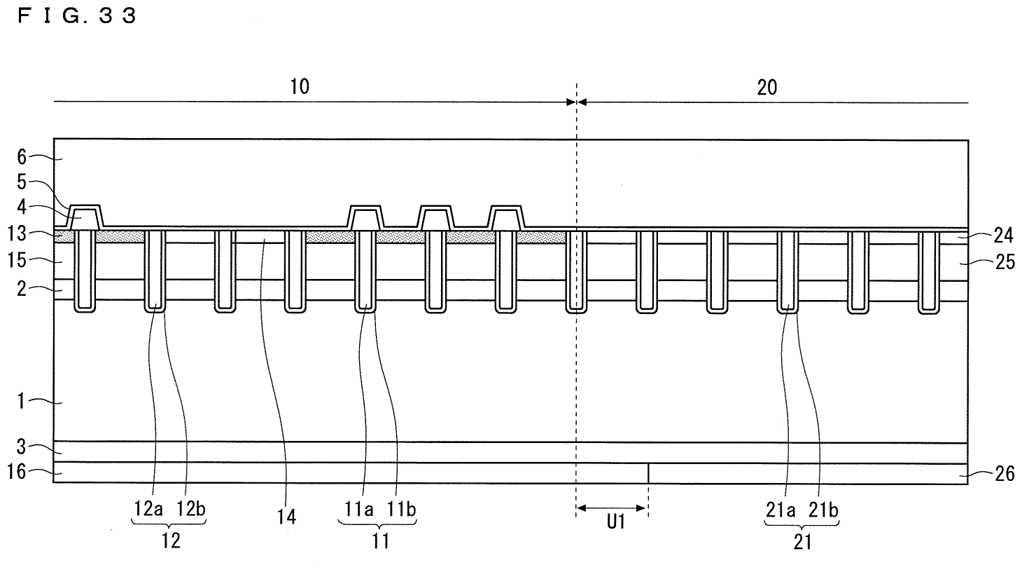

Next, as illustrated in FIG. 33, the n⁺-type cathode layer 26 is formed in the diode region 20. For example, the n⁺-type cathode layer 26 may be formed by implanting the phosphorus (P). As illustrated in FIG. 33, phosphorus is selectively implanted from the second main surface side by mask processing such that a boundary between the p-type collector layer 16 and the n⁺-type cathode layer 26 is located at a position at the distance U1 from the boundary between the IGBT region 10 and the diode region 20 toward the side of the diode region 20. An implantation amount of the n-type impurity forming the n⁺-type cathode layer 26 is larger than the implantation amount of the p-type impurity forming the p-type collector layer 16. In FIG. 33, depths of the p-type collector layer 16 and the n⁺-type cathode layer 26 from the second main surface are the same, but the depth of the n⁺-type cathode layer 26 is equal to or greater than the depth of the p-type collector layer 16. In the region where the n⁺-type cathode layer 26 is formed, the n-type semiconductor is required to be formed by implanting the n-type impurity into the region into which the p-type impurity is implanted, so that the concentration of the implanted p-type impurity is made higher than the concentration of the n-type impurity in the entire region where the n⁺-type cathode layer 26 is formed.

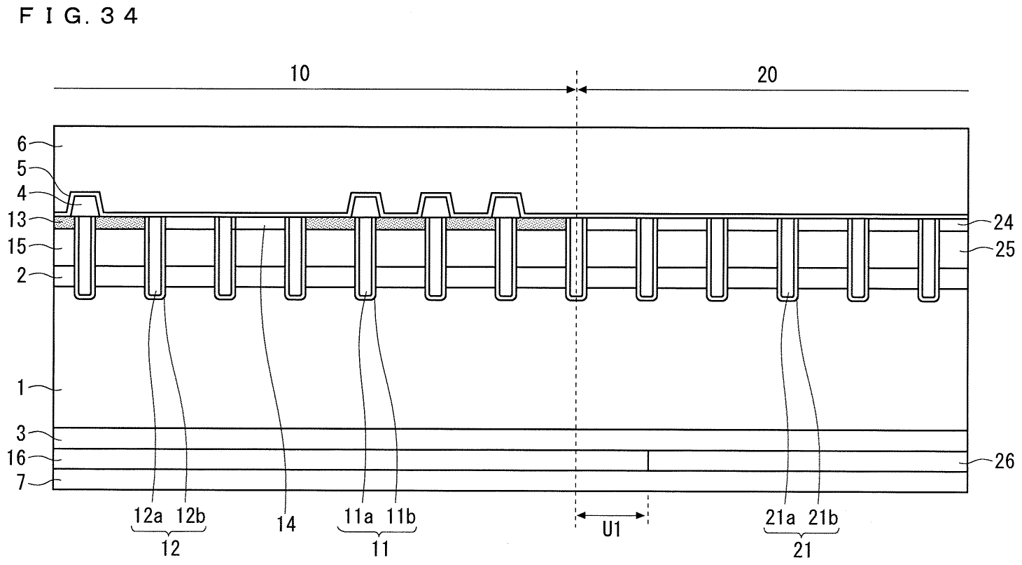

Next, as illustrated in FIG. 34, the collector electrode 7 is formed on the second main surface of the semiconductor substrate. The collector electrode 7 is formed over the entire surfaces of the IGBT region 10, the diode region 20, and the termination region 30 on the second main surface. The collector electrode 7 may be formed over the entire second main surface of the n-type wafer that is the semiconductor substrate. The collector electrode 7 may be formed by depositing an aluminum silicon alloy (Ai-Si-based alloy), titanium (Ti), or the like by PVD such as sputtering or vapor deposition, or the collector electrode 7 may be formed by laminating a plurality of metals such as an aluminum silicon alloy, titanium, nickel, or gold. Furthermore, a metal film may be further formed on the metal film formed by PVD by electroless plating or electrolytic plating to form the collector electrode 7.

The semiconductor device 100 is manufactured by the above processes. A plurality of the semiconductor devices 100 are manufactured in a matrix on one n-type wafer, so that the semiconductor devices 100 are completed by cutting the wafer into the individual semiconductor devices 100 by laser dicing or blade dicing.

### (12) Method of Manufacturing Semiconductor Device According to Present Preferred Embodiment

The semiconductor device according to the present preferred embodiment can be formed by forming the first trench 51 and the second trench 52 as the trenches 8 and further forming the p-type bottom layer 60 by ion-implanting a p-type impurity into a bottom of the second trench 52 in the manufacturing method described above. In a process of forming the p-type bottom layer 60, the p-type impurity may be ion-implanted into the entire bottom surface of the second trench 52, but it is preferable to ion-implant the p-type impurity only into a central portion of the second trench 52 in order to reduce the widening of the p-type bottom layer 60 in the lateral direction.

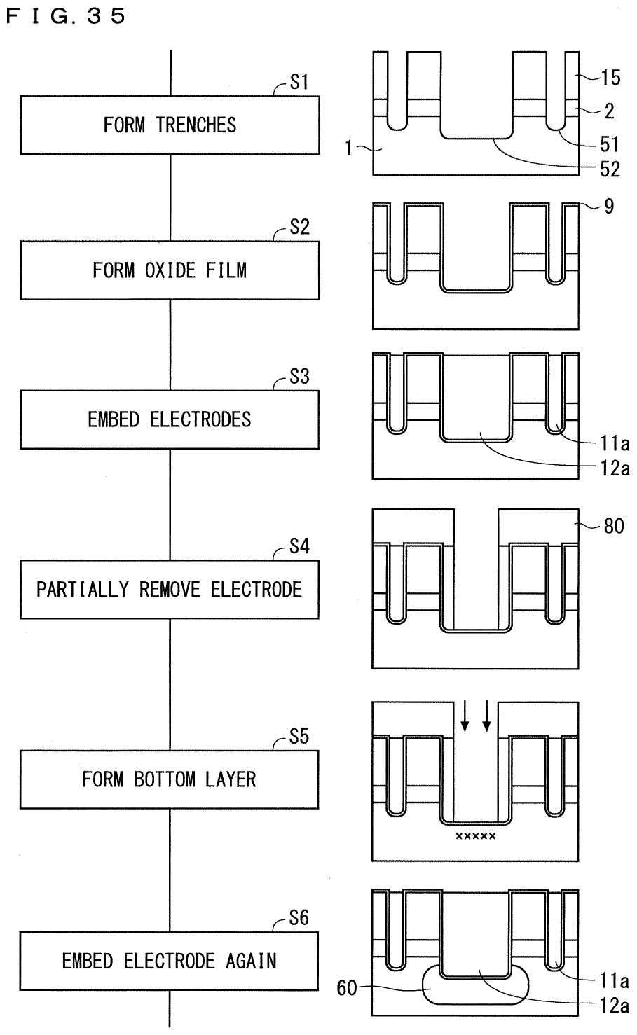

A method of manufacturing the semiconductor device according to the present preferred embodiment will be described more specifically with reference to a flowchart of FIG. 35. Since the semiconductor device according to the present preferred embodiment can be formed by a method similar to the example of the manufacturing method described above, differences from the example of the manufacturing method described above will be described here. FIG. 35 representatively illustrates a manufacturing method in a case where the first trench 51 and the second trench 52 are formed in the IGBT region 10. A method similar to that in FIG. 35 may be used in a case where the first trench 51 and the second trench 52 are formed in the diode region 20 or the termination region 30.

In the method of manufacturing the semiconductor device according to the present preferred embodiment, the first trench 51 and the second trench 52 are formed in the process of forming the trenches 8 on the first main surface of the semiconductor substrate (step S1). In this process, the second trench 52 needs to be deeper than the first trench 51. In general, since a wider trench is formed deeper, the second trench 52 becomes deeper than the first trench 51 if the first trench 51 and the second trench 52 are formed under the same etching condition. Therefore, the first trench 51 and the second trench 52 can be formed at the same time, and it is not necessary to consider alignment between the first trench 51 and the second trench 52.

Subsequently, the oxide film 9 to be the gate trench insulating film 11b and the dummy trench insulating film 12b is formed on inner surfaces of the first trench 51 and the second trench 52 (step S2). Then, polysilicon doped with an n-type or p-type impurity is deposited to form the gate trench electrode 11a and the dummy trench electrode 12a in the first trench 51 and the second trench 52, respectively (step S3).

Next, a resist mask 80 having an opening at the central portion of the second trench 52 is formed on a first main surface of a semiconductor substrate using a photolithography technique, and a central portion of the dummy trench electrode 12a in the second trench 52 is removed by etching using the resist mask 80 as a mask (step S4). Furthermore, the p-type bottom layer 60 is formed at a portion where the dummy trench electrode 12a has been removed, that is, at a bottom of the central portion of the second trench 52 by ion implantation of a p-type impurity using the resist mask 80 as a mask (step S5).

Thereafter, polysilicon doped with an n-type or p-type impurity is deposited again to form the dummy trench electrode 12a again in the portion where the dummy trench electrode 12a has been removed in step S4 (step S6). Furthermore, heat treatment for activating the impurity in the p-type bottom layer 60 is performed. In step S6, the portion of the dummy trench electrode 12a removed in step S4 may be embedded with a metal film such as aluminum or tungsten, or may be embedded with an insulating film such as a thermal oxide film of polysilicon or a CVD oxide film.

According to this method, since the p-type impurity can be ion-implanted only in the central portion of the second trench 52, the widening of the p-type bottom layer 60 in the lateral direction can be prevented.

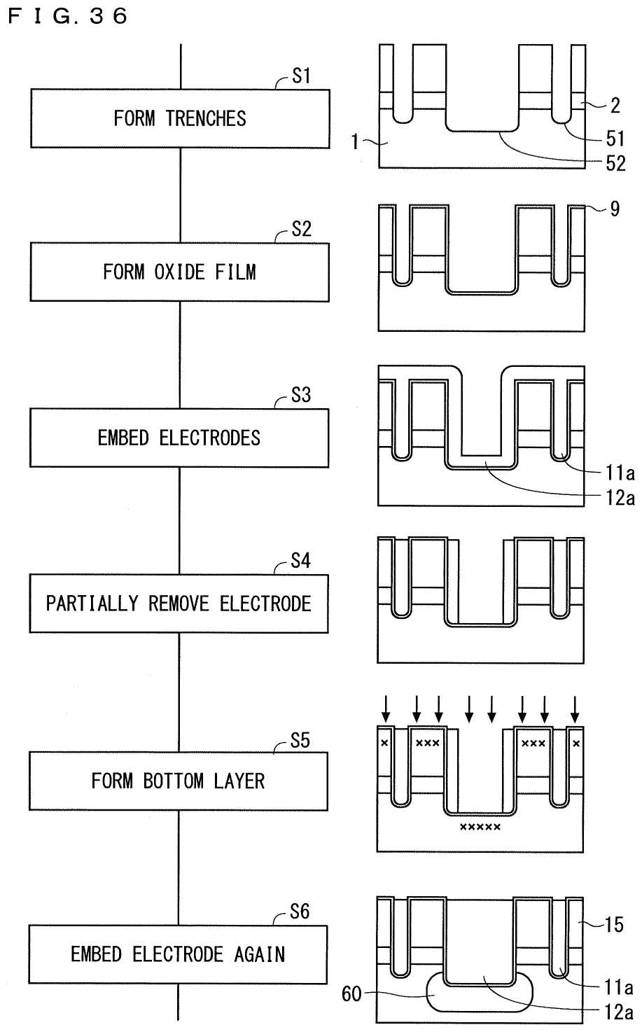

FIG. 36 illustrates another example of the method of manufacturing the semiconductor device according to the present preferred embodiment. In the manufacturing method of FIG. 36, a process of forming the first trench 51 and the second trench 52 (step S1) is performed on a semiconductor substrate on which the p-type base layer 15 is not formed.

After the first trench 51 and the second trench 52 are formed, the oxide film 9 to be the gate trench insulating film 11b and the dummy trench insulating film 12b is formed on inner surfaces thereof (step S2). Then, polysilicon doped with an n-type or p-type impurity is deposited to form the gate trench electrode 11a and the dummy trench electrode 12a in the first trench 51 and the second trench 52, respectively (step S3). At this time, a thickness of polysilicon to be deposited is adjusted such that the entire first trench 51 is filled with the gate trench electrode 11a and the dummy trench electrode 12a is formed on a side wall and a bottom of the second trench 52.

Next, when polysilicon is etched back, a central portion of the dummy trench electrode 12a in the second trench 52 is removed while leaving the gate trench electrode 11a in the first trench 51 and the dummy trench electrode 12a formed on the side wall of the second trench 52 (step S4). In this state, a p-type impurity is ion-implanted into a first main surface of the semiconductor substrate to form the p-type bottom layer 60 at a portion where the dummy trench electrode 12a has been removed, that is, at a bottom of a central portion of the second trench 52 (step S5). At the same time, the p-type base layer 15 is formed in the vicinity of the first main surface of the semiconductor substrate.

Thereafter, polysilicon doped with an n-type or p-type impurity is deposited again to form the dummy trench electrode 12a again in the portion where the dummy trench electrode 12a has been removed in step S4 (step S6). Furthermore, heat treatment for activating the impurity in the p-type bottom layer 60 is performed.

Also in the manufacturing method of FIG. 36, since the p-type impurity can be ion-implanted only in the central portion of the second trench 52, the widening of the p-type bottom layer 60 in the lateral direction can be prevented.

In particular, in the manufacturing method of FIG. 36, it is not necessary to add a photolithography process since the central portion of the dummy trench electrode 12a can be selectively removed without using the resist mask 80. In addition, alignment of the p-type bottom layer 60 with respect to the second trenches 52 can be achieved by self-alignment. Furthermore, there is also an advantage that impurity implantation processes can be reduced since the p-type bottom layer 60 and the p-type base layer 15 can be simultaneously formed. Therefore, the manufacturing method of FIG. 36 can greatly contribute to simplification of manufacturing processes and reduction of manufacturing cost.

In the above description of the preferred embodiment, an RC-IGBT having an IGBT region and a diode region is mainly described as an example of the semiconductor device, but the semiconductor device may be a single IGBT having no diode region as illustrated in FIG. 1. Furthermore, the semiconductor device may be a semiconductor device having a MOSFET region obtained by replacing the p-type collector layer 16 of the IGBT region with the n⁺-type cathode layer 26, or may be a single MOSFET having no diode region. In any semiconductor device, the same effects as those of the preferred embodiment of the RC-IGBT can be obtained.

Note that the above-described preferred embodiment can be appropriately modified or omitted.

### APPENDIXES

Hereinafter, various aspects of the present disclosure will be collectively described as appendixes.

### Appendix 1

A semiconductor device comprising:
a semiconductor substrate having a drift layer of a first conductivity type between a first main surface and a second main surface opposite to the first main surface;
a plurality of trenches formed on the first main surface of the semiconductor substrate;
an insulating film formed on an inner surface of each of the plurality of trenches; and
an electrode embedded in each of the plurality of trenches through the insulating film,
wherein the plurality of trenches includes:
a first trench; and
a second trench deeper than the first trench and wider than the first trench, and
a bottom layer of a second conductivity type, in contact with a bottom of the second trench and not in contact with the first trench, is formed under the second trench.

### Appendix 2

The semiconductor device according to Appendix 1, further comprising:
a base layer of the second conductivity type formed on a side facing the first main surface of the drift layer in the semiconductor substrate; and
a carrier stored layer of the first conductivity type formed between the base layer and the drift layer, wherein the bottom layer is in contact with the carrier stored layer.

### Appendix 3

The semiconductor device according to Appendix 2, wherein a bottom of the carrier stored layer is deeper than a bottom of the first trench and shallower than a bottom of the bottom layer.

### Appendix 4

The semiconductor device according to any one of Appendixes 1 to 3, wherein
the semiconductor substrate includes a termination region in an outer peripheral portion,
the semiconductor substrate in the termination region includes a termination well layer of the second conductivity type formed on the side facing the first main surface of the drift layer,
an outermost trench, which is the trench disposed on an outermost side in the termination region, is the second trench,
the bottom layer is formed under the outermost trench, and
a bottom of the termination well layer is shallower than a bottom of the outermost trench.

### Appendix 5

The semiconductor device according to any one of Appendixes 1 to 3, wherein the semiconductor substrate includes a cathode layer of the first conductivity type in contact with the second main surface on a side facing the second main surface of the drift layer.

### Appendix 6

The semiconductor device according to any one of Appendixes 1 to 3, wherein the semiconductor substrate includes a collector layer of the second conductivity type in contact with the second main surface on a side facing the second main surface of the drift layer.

### Appendix 7

The semiconductor device according to any one of Appendixes 1 to 6, wherein
the semiconductor substrate includes:
an IGBT region in which an IGBT having the electrode embedded in the first trench or the second trench as a gate electrode is formed; and
a diode region in which an anode layer of the second conductivity type in contact with the first main surface is disposed on a side facing the first main surface of the drift layer, and a cathode layer of the first conductivity type in contact with the second main surface is disposed on a side facing the second main surface of the drift layer.

### Appendix 8

The semiconductor device according to Appendix 7, wherein the first trench, the second trench, and the bottom layer are also disposed in the diode region.

### Appendix 9

A method of manufacturing a semiconductor device, the method comprising:
(a) preparing a semiconductor substrate having a drift layer of a first conductivity type between a first main surface and a second main surface opposite to the first main surface;
(b) forming a first trench and a second trench, wider than the first trench, on the first main surface of the semiconductor substrate;
(c) forming an insulating film on an inner surface of each of the first trench and the second trench;
(d) forming an electrode in each of the first trench and the second trench after the forming the insulating film;
(e) removing a central portion of the electrode in the second trench;
(f) forming a bottom layer by ion implantation of an impurity of a second conductivity type into a bottom of the second trench in a portion from which the electrode has been removed;
(g) forming the electrode again in the portion from which the electrode has been removed after the forming the bottom layer; and
(h) performing heat treatment for activating the bottom layer.

### Appendix 10

The method of manufacturing a semiconductor device according to Appendix 9, wherein
the step (e) is performed by etching back the electrode, and
a base layer of the second conductivity type is formed on a side facing the first main surface of the drift layer together with the bottom layer by the ion implantation in the step (f).

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate having a drift layer of a first conductivity type between a first main surface and a second main surface opposite to the first main surface;
a plurality of trenches formed on the first main surface of the semiconductor substrate;
an insulating film formed on an inner surface of each of the plurality of trenches; and
an electrode embedded in each of the plurality of trenches through the insulating film,
wherein the plurality of trenches includes:
a first trench; and
a second trench deeper than the first trench and wider than the first trench, and
a bottom layer of a second conductivity type, in contact with a bottom of the second trench and not in contact with the first trench, is formed under the second trench.

2. The semiconductor device according to claim 1, further comprising:
a base layer of the second conductivity type formed on a side facing the first main surface of the drift layer in the semiconductor substrate; and
a carrier stored layer of the first conductivity type formed between the base layer and the drift layer,
wherein the bottom layer is in contact with the carrier stored layer.

3. The semiconductor device according to claim 2, wherein a bottom of the carrier stored layer is deeper than a bottom of the first trench and shallower than a bottom of the bottom layer.

4. The semiconductor device according to claim 1, wherein
the semiconductor substrate includes a termination region in an outer peripheral portion,
the semiconductor substrate in the termination region includes a termination well layer of the second conductivity type formed on the side facing the first main surface of the drift layer,
an outermost trench, which is the trench disposed on an outermost side in the termination region, is the second trench,
the bottom layer is formed under the outermost trench, and
a bottom of the termination well layer is shallower than a bottom of the outermost trench.

5. The semiconductor device according to claim 1, wherein the semiconductor substrate includes a cathode layer of the first conductivity type in contact with the second main surface on a side facing the second main surface of the drift layer.

6. The semiconductor device according to claim 1, wherein the semiconductor substrate includes a collector layer of the second conductivity type in contact with the second main surface on a side facing the second main surface of the drift layer.

7. The semiconductor device according to claim 1, wherein
the semiconductor substrate includes:
an IGBT region in which an IGBT having the electrode embedded in the first trench or the second trench as a gate electrode is formed; and
a diode region in which an anode layer of the second conductivity type in contact with the first main surface is disposed on a side facing the first main surface of the drift layer, and a cathode layer of the first conductivity type in contact with the second main surface is disposed on a side facing the second main surface of the drift layer.

8. The semiconductor device according to claim 7, wherein the first trench, the second trench, and the bottom layer are also disposed in the diode region.

9. A method of manufacturing a semiconductor device comprising:
(a) preparing a semiconductor substrate having a drift layer of a first conductivity type between a first main surface and a second main surface opposite to the first main surface;
(b) forming a first trench and a second trench, wider than the first trench, on the first main surface of the semiconductor substrate;
(c) forming an insulating film on an inner surface of each of the first trench and the second trench;
(d) forming an electrode in each of the first trench and the second trench after the forming the insulating film;
(e) removing a central portion of the electrode in the second trench;
(f) forming a bottom layer by ion implantation of an impurity of a second conductivity type into a bottom of the second trench in a portion from which the electrode has been removed;
(g) forming the electrode again in the portion from which the electrode has been removed after the forming the bottom layer; and
(h) performing heat treatment for activating the bottom layer.

10. The method of manufacturing a semiconductor device according to claim 9, wherein
the step (e) is performed by etching back the electrode, and
a base layer of the second conductivity type is formed on a side facing the first main surface of the drift layer together with the bottom layer by the ion implantation in the step (f).
